(19) United States
(12) Patent Application Publication
(10) Pub. No.: US 2025/0271751 A1
(43) Pub. Date: Aug. 28, 2025

(54) PHOTOSENSITIVE COMPOSITION, PHOTOSENSITIVE FILM, LOWER LAYER FILM, METHOD FOR PRODUCING STRUCTURE HAVING PHASE-SEPARATED STRUCTURE, AND COMPOUND

(71) Applicant: TOKYO OHKA KOGYO CO., LTD., Kawasaki-shi (JP)

(72) Inventors: Ryutaro SUGAWARA, Kawasaki-shi (JP); Yuki KOKITA, Kawasaki-shi (JP); Takuya UEHARA, Kawasaki-shi (JP); Takehiro SESHIMO, Kawasaki-shi (JP); Takahiro DAZAI, Kawasaki-shi (JP)

(21) Appl. No.: 19/062,493

(22) Filed: Feb. 25, 2025

(30) Foreign Application Priority Data
Feb. 28, 2024 (JP) 2024-028505

(51) Int. Cl. G03F 7/00; C08F 297/02; C08G 63/08; C08G 63/133; C08G 63/91; C09D 153/00; G03F 7/004; G03F 7/09

(52) U.S. Cl. CPC G03F 7/0002; C08F 297/026; C08G 63/08; C08G 63/133; C08G 63/91; C09D 153/00; G03F 7/0045; G03F 7/094

(57) ABSTRACT

A photosensitive composition which can change polarity of a surface of the film by exposure even under low exposure dose and low post-baking temperature conditions, a photosensitive film, a lower layer film, a method for producing a structure having a phase-separated structure, and a compound. The photosensitive composition includes an acid-degradable compound and a photoacid generating agent, and the acid-degradable compound (A) is one or more compounds represented by any of Formulae (A1) to (A4) below:

R^{a1}—(—CH₂—CR^{a2}R^{a3}—)ₙ—R^{a4}—O—(—CO—R^{a5}—CO—)—O—R^{a6}—R^{a7} (A1)

R^{a1}—(—CH₂—CR^{a2}R^{a3}—)ₙ—R^{a4}—O—(—CO—R^{a5}—O—)—CO—R^{a6}—R^{a7} (A2)

R^{a1}—(—CH₂—CR^{a2}R^{a3}—)ₙ—R^{a4}—CO—(—O—R^{a5}—CO—)—O—R^{a6}—R^{a7} (A3)

R^{a1}—(—CH₂—CR^{a2}R^{a3}—)ₙ—R^{a4}—CO—(—O—R^{a5}—O—)—CO—R^{a6}—R^{a7} (A4).

This application claims priority to Japanese Patent Application No. 2024-028505, filed Feb. 28, 2024, the entire content of which is incorporated herein by reference.

### BACKGROUND OF THE INVENTION

### Field of the Invention

The present invention relates to a photosensitive composition, a photosensitive film, a method for producing a structure having a lower layer film having a phase-separated structure, and a compound.

### Related Art

In recent years, following further miniaturization of a large-scale integrated circuit (LSI), a technique for processing a finer structure has been demanded. For such a demand, a technique has been developed for forming a finer pattern utilizing a phase-separated structure formed by self-organization of a block copolymer in which blocks incompatible with each other are bonded.

The above-mentioned block copolymer is separated (phase-separated) in a microregion due to repulsion between the blocks incompatible with each other and forms a structure with a regular periodic structure by a heat treatment, etc. Specifically, the periodic structure may be cylindrical (columnar), lamellar (plate-like), or spheric (spherical).

In order to utilize the phase-separated structure of the block copolymer, it is essential for a self-organized nanostructure formed by microphase separation to be formed only in a specific region and oriented in a desired direction. In order to control a position and orientation of the nanostructure as described above, processes such as graphoepitaxy for controlling a phase separation pattern by a guide pattern and chemical epitaxy for controlling a phase separation pattern based on a difference in a chemical state of a substrate have been proposed.

For example, Patent Document 1 discloses a lower layer including an acid-sensitive copolymer including an acid-degradable group, an attachment group, and a functional group; and a photoacid generating agent to lithographically change a surface polarity and control a phase separation pattern.
Patent Document 1: Japanese Unexamined Patent Application, Publication No. 2018-139007

### SUMMARY OF THE INVENTION

In the invention described in Patent Document 1, an acid generated from the photoacid generating agent upon exposure degrades the acid-degradable group in a side chain of the copolymer to form a polar region. However, this invention has the problem of requiring a high exposure dose and a high post-baking temperature.

The present invention has been made in view of such existing circumstances, and an object of the present invention is to provide a photosensitive composition which can change polarity of a surface of a film by exposure even under low exposure dose and low post-baking temperature conditions, a photosensitive film, a lower layer film, a method for producing a structure having a phase-separated structure, and a compound.

As a result of extensive studies to solve the above problem, the present invention has been completed based on findings that a photosensitive composition including a predetermined acid-degradable compound (A) and a photoacid generating agent (B) can be used to solve the above problem. Specifically, the present invention provides the following aspects.

A first aspect of the present invention relates to a photosensitive composition including:
an acid-degradable compound (A); and a photoacid generating agent (B),
the acid-degradable compound (A) being one or more compounds represented by any of Formulae (A1) to (A4) below:

R^{a1}—(—CH₂—CR^{a2}R^{a3}—)ₙ—R^{a4}—O—(—CO—R^{a5}—CO—)—O—R^{a6}—R^{a7} (A1)

R^{a1}—(—CH₂—CR^{a2}R^{a3}—)ₙ—R^{a4}—O—(—CO—R^{a5}—O—)—CO—R^{a6}—R^{a7} (A2)

R^{a1}—(—CH₂—CR^{a2}R^{a3}—)ₙ—R^{a4}—CO—(—O—R^{a5}—CO—)—O—R^{a6}—R^{a7} (A3)

R^{a1}—(—CH₂—CR^{a2}R^{a3}—)ₙ—R^{a4}—CO—(—O—R^{a5}—O—)—CO—R^{a6}—R^{a7} (A4)

in which R^{a1} is an alkyl group, R^{a2} is a hydrogen atom or an alkyl group, R^{a3} is an aromatic group that may have a substituent, R^{a4} is an alkylene group, R^{a5} is a residue in which a carboxy group or a hydroxy group as a terminal group is removed from a linear aliphatic polyester, R^{a6} is an alkylene group, R^{a7} is a hydroxy group, a carboxy group, a phosphate group, a mercapto group, or an amino group, and n is a number of replications of a building block represented by —CH₂—CR^{a2}R^{a3}— and is an integer of 2 or more.

A second aspect of the present invention relates to a photosensitive film including:
an acid-degradable compound (A); and a photoacid generating agent (B),
the acid-degradable compound (A) being one or more compounds represented by any of Formulae (A1) to (A4) below:

R^{a1}—(—CH₂—CR^{a2}R^{a3}—)ₙ—R^{a4}—O—(—CO—R^{a5}—CO—)—O—R^{a6}—R^{a7} (A1)

R^{a1}—(—CH₂—CR^{a2}R^{a3}—)ₙ—R^{a4}—O—(—CO—R^{a5}—O—)—CO—R^{a6}—R^{a7} (A2)

R^{a1}—(—CH₂—CR^{a2}R^{a3}—)ₙ—R^{a4}—CO—(—O—R^{a5}—CO—)—O—R^{a6}—R^{a7} (A3)

R^{a1}—(—CH₂—CR^{a2}R^{a3}—)ₙ—R^{a4}—CO—(—O—R^{a5}—O—)—CO—R^{a6}—R^{a7} (A4)
in which R^{a1} is an alkyl group, R^{a2} is a hydrogen atom or an alkyl group, R^{a3} is an aromatic group that may have a substituent, R^{a4} is an alkylene group, R^{a5} is a residue in which a carboxy group or a hydroxy group as a terminal group is removed from a linear aliphatic polyester, R^{a6} is an alkylene group, R^{a7} is a hydroxy group, a carboxy group, a phosphate group, a mercapto group, or an amino group, and n is a number of replications of a building block represented by —CH₂—CR^{a2}R^{a3}— and is an integer of 2 or more.

A third aspect of the present invention relates to a lower layer film for use as a template for phase-separating a block copolymer,
the lower layer film being formed by exposing the photosensitive film according to the second aspect in a position-selective manner, and
the lower layer film including: an exposed region; and an unexposed region, the exposed region and the unexposed region differing in hydrophilicity from each other.

A fourth aspect of the present invention relates to a method for forming a structure having a phase-separated structure, the method including:
forming the lower layer film according to the third aspect on a substrate;
forming an upper layer film on the lower layer film, the upper layer film including a block copolymer; and
phase-separating the block copolymer in the upper layer film.

A fifth aspect of the present invention relates to a compound represented by any of Formulae (A1) to (A4) below:

R^{a1}—(—CH₂—CR^{a2}R^{a3}—)ₙ—R^{a4}—O—(—CO—R^{a5}—CO—)—O—R^{a6}—R^{a7} (A1)

R^{a1}—(—CH₂—CR^{a2}R^{a3}—)ₙ—R^{a4}—O—(—CO—R^{a5}—O—)—CO—R^{a6}—R^{a7} (A2)

R^{a1}—(—CH₂—CR^{a2}R^{a3}—)ₙ—R^{a4}—CO—(—O—R^{a5}—CO—)—O—R^{a6}—R^{a7} (A3)

R^{a1}—(—CH₂—CR^{a2}R^{a3}—)ₙ—R^{a4}—CO—(—O—R^{a5}—O—)—CO—R^{a6}—R^{a7} (A4)

in which R^{a1} is an alkyl group, R^{a2} is a hydrogen atom or an alkyl group, R^{a3} is an aromatic group that may have a substituent, R^{a4} is an alkylene group, R^{a5} is a residue in which a carboxy group or a hydroxy group as a terminal group is removed from a linear aliphatic polyester, R^{a6} is an alkylene group, R^{a7} is a hydroxy group, a carboxy group, a phosphate group, a mercapto group, or an amino group, and n is a number of replications of a building block represented by —CH₂—CR^{a2}R^{a3}— and is an integer of 2 or more.

The present invention can provide a photosensitive composition which can change polarity of a surface of a film by exposure even under low exposure dose and low post-baking temperature conditions, a photosensitive film, a lower layer film, a method for producing a structure having a phase-separated structure, and a compound.

### BRIEF DESCRIPTION OF THE DRAWINGS

FIG. 1 is a schematic process drawing illustrating one exemplary embodiment of Step (i).

### DETAILED DESCRIPTION OF THE INVENTION

Although embodiments of the present invention will be described hereafter in detail, the present invention is not limited to the embodiments below in any way and can be implemented with modifications as appropriate within the scope of the object of the present invention.

### <<Photosensitive Composition>>

A photosensitive composition includes an acid-degradable compound (A) and a photoacid generating agent (B). The acid-degradable compound (A) is one or more compounds represented by any of Formulae (A1) to (A4) below:

R^{a1}—(—CH₂—CR^{a2}R^{a3}—)ₙ—R^{a4}—O—(—CO—R^{a5}—CO—)—O—R^{a6}—R^{a7} (A1)

R^{a1}—(—CH₂—CR^{a2}R^{a3}—)ₙ—R^{a4}—O—(—CO—R^{a5}—O—)—CO—R^{a6}—R^{a7} (A2)

R^{a1}—(—CH₂—CR^{a2}R^{a3}—)ₙ—R^{a4}—CO—(—O—R^{a5}—CO—)—O—R^{a6}—R^{a7} (A3)

R^{a1}—(—CH₂—CR^{a2}R^{a3}—)ₙ—R^{a4}—CO—(—O—R^{a5}—O—)—CO—R^{a6}—R^{a7} (A4)
in which R^{a1} is an alkyl group, R^{a2} is a hydrogen atom or an alkyl group, R^{a3} is an aromatic group that may have a substituent, R^{a4} is an alkylene group, R^{a5} is a residue in which a carboxy group or a hydroxy group as a terminal group is removed from a linear aliphatic polyester, R^{a6} is an alkylene group, R^{a7} is a hydroxy group, a carboxy group, a phosphate group, a mercapto group, or an amino group, and n is a number of replications of a building block represented by —CH₂—CR^{a2}R^{a3}— and is an integer of 2 or more.

The residue in which a carboxy group or a hydroxy group as a terminal group is removed from a linear aliphatic polyester for R^{a5} is hereinafter also referred to as “polyester residue”.

By applying a photosensitive composition to a substrate to form a photosensitive film, an acid-degradable compound (A) is fixed onto a substrate via a functional group for R^{a7} to form a polymer brush layer having a less polar group represented by R^{a1}—(—CH₂—CR^{a2}R^{a3}—)ₙ— on a surface of the film. When the photosensitive film is exposed, an acid generated from a photoacid generating agent (B) hydrolyzes an ester bond in a polyester residue for R^{a5} or an ester bond adjacent to the polyester residue, and thus a highly polar linear aliphatic polyester appears on the surface of the film. Therefore, a pattern having an exposed region and an unexposed region differing in hydrophilicity from each other can be formed by exposing the photosensitive film in a position-selective manner. Since the acid-degradable compound (A) has many ester bonds in a polymer main chain, it is believed that polarity of the surface of the film can be changed upon exposure even under low exposure dose and low post-baking temperature conditions.

### <Acid Degradable Compound (A)>

A photosensitive composition includes an acid-degradable compound (A). The acid-degradable compound (A) is one or more compounds represented by any of Formulae (A1) to (A4). Among these, a compound represented by Formula (A2) is preferred.

In Formulae (A1) to (A4), n R^{a2}s or n R^{a3}s may be the same as or different from each other. The acid-degradable compound (A) may include only a compound having the same polyester residue, or may include two or more compounds having different polyester residues from each other.

An alkyl group for R^{a1} preferably has 1 or more and 20 or less carbon atoms, more preferably 1 or more and 10 or less carbon atoms, and further preferably 1 or more and 5 or less carbon atoms. Examples of the alkyl group for R^{a1} include a methyl group, an ethyl group, an n-propyl group, an iso-propyl group, an n-butyl group, a sec-butyl group, an iso-butyl group, a tert-butyl group, an n-pentyl group, an n-hexyl group, an n-heptyl group, an n-octyl group, an n-nonyl group, an n-decyl group, etc.

An alkyl group for R^{a2} preferably has 1 or more and 10 or less carbon atoms and more preferably 1 or more and 5 or less carbon atoms. The alkyl group for R^{a2} may be the same as the alkyl group for Rai. R^{a2} is preferably a hydrogen atom or an alkyl group having 1 or more and 5 or less carbon atoms and more preferably a hydrogen atom or a methyl group.

An aromatic group that may have a substituent for R^{a3} may be an aromatic hydrocarbon group that may have a substituent or an aromatic heterocyclic group that may have a substituent and is preferably an aromatic hydrocarbon group that may have a substituent and more preferably an aromatic hydrocarbon group.

A type of the aromatic hydrocarbon group is not particularly limited as long as the desired effect is not impaired. The aromatic hydrocarbon group may be a monocyclic aromatic group, a group formed by fusion of two or more aromatic hydrocarbon groups, or a group formed by two or more aromatic hydrocarbon groups bonded by a single bond. Examples of the aromatic hydrocarbon group include a phenyl group, a naphthyl group, a biphenylyl group, an anthryl group, a phenanthrenyl group, etc. Among these, a phenyl group is preferred.

A type of the aromatic heterocyclic group is not particularly limited as long as the desired effect is not impaired. The aromatic heterocyclic group may be a monocyclic group or a polycyclic group. Examples of the aromatic heterocyclic group include a pyridyl group, a furyl group, a thienyl group, an imidazolyl group, a pyrazolyl group, an oxazolyl group, a thiazolyl group, an isoxazolyl group, an isothiazolyl group, a benzoxazolyl group, a benzothiazolyl group, a benzoimidazolyl group, etc.

Examples of a substituent that the aromatic group has include an alkyl group that may have an oxygen atom and/or a silicon atom, a hydroxy group, a nitro group, a halogen atom, an acetoxy group, etc. Among these, an alkyl group that may have an oxygen atom and/or a silicon atom is preferred.

The alkyl group that may have an oxygen atom and/or a silicon atom is preferably an alkyl group that may be interrupted by an oxygen atom or may be substituted with an alkylsilyl group. Specific examples thereof include an alkyl group, an alkylsilyl group, an alkylsilylalkyl group, an alkylsilyloxy group, an alkylsilyloxyalkyl group, an alkoxy group, etc.

Examples of the alkyl group include a methyl group, an ethyl group, an n-propyl group, an isopropyl group, an n-butyl group, a sec-butyl group, a tert-butyl group, etc.

The alkylsilyl group is preferably a trialkylsilyl group. Specific examples thereof include a trimethylsilyl group, etc. The alkylsilylalkyl group is preferably a trialkylsilylalkyl group. Specific examples thereof include a trimethylsilylmethyl group, a 2-trimethylsilylethyl group, a 3-trimethylsilyl-n-propyl group, etc. The alkylsilyloxy group is preferably a trialkylsilyloxy group. Specific examples thereof include a trimethylsilyloxy group, etc. The alkylsilyloxyalkyl group is preferably a trialkylsilyloxyalkyl group. Specific examples thereof include a trimethylsilyloxymethyl group, a 2-trimethylsilyloxyethyl group, a 3-trimethylsilyloxy-n-propyl group, etc. Examples of the alkoxy group include a methoxy group, an ethoxy group, an n-propoxy group, an isopropoxy group, an n-butoxy group, a sec-butoxy group, a tert-butoxy group, etc.

The alkyl group that may be interrupted by an oxygen atom or may be substituted with an alkylsilyl group has preferably 1 or more and 10 or less carbon atoms, more preferably 1 or more and 5 or less carbon atoms, further preferably 1 or more and 3 or less carbon atoms, and particularly preferably 1 or 2 carbon atoms in total.

A number of a substituent that the aromatic group has is preferably an integer of 0 or more and 3 or less, preferably 0 or 1, and further preferably 0.

n is preferably 2 or more and 200 or less, more preferably 10 or more and 150 or less, and further preferably 30 or more and 100 or less.

An alkylene group for R^{a4} preferably has 1 or more and 20 or less carbon atoms, more preferably 1 or more and 10 or less carbon atoms, and further preferably 1 or more and 5 or less carbon atoms. The alkylene group for R^{a4} may be linear or branched, and is preferably linear. Examples of the alkylene group for R^{a4} include a methylene group, an ethane-1,2-diyl group, a propane-1,2-diyl group, a propane-1,3-diyl group, a butane-1,4-diyl group, a pentane-1,5-diyl group, etc.

A polyester residue for R^{a5} is a residue in which a carboxy group or a hydroxy group as a terminal group is removed from a linear aliphatic polyester. The linear aliphatic polyester may be a homopolyester or a copolyester. The copolyester is composed of two or more different types of linear aliphatic polyester blocks. The two or more different types of linear aliphatic polyester blocks may be a plurality of types of homopolyester blocks, a plurality of types of copolyester blocks, or a combination of one or more homopolyester blocks and one or more copolyester blocks.

Examples of the linear aliphatic polyester from which the polyester residue for R^{a5} is produced include a polycondensate of an aliphatic hydroxycarboxylic acid, a ring-opened polymer of a lactone, a polycondensate of an aliphatic dicarboxylic acid with an aliphatic diol, etc. Among these, a polycondensate of an aliphatic hydroxycarboxylic acid or a ring-opened polymer of a lactone is preferred.

The aliphatic hydroxycarboxylic acid preferably has 2 or more and 20 or less carbon atoms, more preferably 2 or more and 10 or less carbon atoms, and further preferably 2 or more and 5 or less carbon atoms. The polycondensate of an aliphatic hydroxycarboxylic acid is preferably a polycondensate of a compound having one hydroxy group and one carboxy group and more preferably a polylactic acid, a polyglycolic acid, or a polyhydroxybutyric acid.

The lactone preferably has 2 or more and 20 or less carbon atoms, more preferably 3 or more and 10 or less carbon atoms, and further preferably 4 or more and 8 or less carbon atoms. The ring-opened polymer of a lactone is preferably a ring-opened polymer of an aliphatic lactone and more preferably polycaprolactone, polybutyrolactone, or polyvalerolactone.

The residue for R^{a5} preferably includes 2 or more and 200 or less ester bonds, more preferably 4 or more and 150 or less ester bonds, and further preferably 6 or more and 100 or less ester bonds from the viewpoint of easiness of achievement of the desired effect.

An alkylene group for R^{a6} preferably has 1 or more and 20 or less carbon atoms, more preferably 1 or more and 10 or less carbon atoms, and further preferably 1 or more and 5 or less carbon atoms. The alkylene group for R^{a6} may be linear or branched, and is preferably linear. The alkylene group for R^{a6} may be the same as the alkylene group for R^{a4}.

R^{a7} is preferably a hydroxy group or a carboxy group and more preferably a carboxy group.

A compound represented by any of Formulae (A1) to (A4) preferably has a number average molecular weight of 1,000 or more and 100,000 or less, more preferably 3,000 or more and 75,000 or less, and further preferably 5,000 or more and 50,000 or less from the viewpoint of easiness of achievement of the desired effect. A dispersity (weight average molecular weight/number average molecular weight) of the compound represented by any of Formulae (A1) to (A4) is not particularly limited, and is preferably 1.0 or more and 1.5 or less, more preferably 1.0 or more and 1.4 or less, and further preferably 1.0 or more and 1.3 or less. As used herein, a number average molecular weight and a weight average molecular weight mean a number average molecular weight and a weight average molecular weight in terms of standard polystyrene as determined by size-exclusion chromatography (SEC).

A method for producing a compound represented by any of Formulae (A1) to (A4) is not particularly limited. For example, a compound represented by Formula (A2) can be produced by the below-mentioned method. First, a compound represented by any of Formulae (A1a) to (A4a) below is reacted with a monomer such as an aliphatic hydroxycarboxylic acid, a dimeric cyclic ester of an aliphatic hydroxycarboxylic acid, a lactone, an aliphatic dicarboxylic acid, or an aliphatic diol to obtain a compound represented by any of Formulae (A1b) to (A4b) below. The compound represented by any of Formulae (A1b) to (A4b) can also be obtained by condensing a compound represented by any of Formulae (A1a) to (A4a) with a linear aliphatic polyester according to a conventional method.

A compound represented by Formula (A1b) or (A3b) below can be used as a compound represented by Formula (A1) or Formula (A3), respectively, because it has a carboxyalkyl terminal group. A compound represented by Formula (A2b) or (A4b) below can be used as a compound represented by Formula (A2) or (A4), respectively, because it has a hydroxyalkyl terminal group.

When R^{a7} is a carboxy group, for example, a compound represented by Formula (A2b) or (A4b) is reacted with an anhydride of an aliphatic dicarboxylic acid such as succinic acid anhydride (succinic anhydride) to obtain a compound represented by Formula (A2) or (A4).

When R^{a7} is a hydroxy group, for example, a compound represented by Formula (A1b) or (A3b) is condensed with an aliphatic diol such as ethylene glycol to obtain a compound represented by Formula (A1) or (A3).

When R^{a7} is a carboxy group, for example, a compound represented by any of Formulae (A1) to (A4) is obtained by etherifying or esterifying a compound represented by any of Formula (A1b) to (A4b) using Hal-R^{a6}—CO—O—R^{a}s according to a conventional method and then deprotecting the resultant to remove R^{a8}. In the formula above, Hal is a halogen atom such as a chlorine atom or a bromine atom. R^{a6} is the same as R^{a6} in Formulae (A1) to (A4). R^{a8} is a tertiary alkyl group such as a tert-butyl group.

When R^{a7} is a hydroxy group, a phosphate group, a mercapto group, or an amino group, a compound represented by any of Formulae (A1) to (A4) is obtained by etherifying or esterifying a compound represented by any of Formulae (A1b) to (A4b) using a compound represented by Hal-R^{a6}—R^{a7} according to a conventional method.

R^{a1} to R^{a5} and n in Formulae (A1a) to (A4a) and (A1b) to (A4b) below are as described for Formulae (A1) to (A4).

R^{a1}—(—CH₂—CR^{a2}R^{a3}—)ₙ—R^{a4}—OH (A1a)

R^{a1}—(—CH₂—CR^{a2}R^{a3}—)ₙ—R^{a4}—OH (A2a)

R^{a1}—(—CH₂—CR^{a2}R^{a3}—)ₙ—R^{a4}—COOH (A3a)

R^{a1}—(—CH₂—CR^{a2}R^{a3}—)ₙ—R^{a4}—COOH (A4a)

R^{a1}—(—CH₂—CR^{a2}R^{a3}—)ₙ—R^{a4}—O—(—CO—R^{a5}—CO—)—OH (A1b)

R^{a1}—(—CH₂—CR^{a2}R^{a3}—)ₙ—R^{a4}—O—(—CO—R^{a5}—O—)—H (A2b)

R^{a1}—(—CH₂—CR^{a2}R^{a3}—)ₙ—R^{a4}—CO—(—O—R^{a5}—CO—)—OH (A3b)

R^{a1}—(—CH₂—CR^{a2}R^{a3}—)ₙ—R^{a4}—CO—(—O—R^{a5}—O—)—H (A4b)

### <Photoacid Generating Agent(B)>

A photosensitive composition includes a photoacid generating agent (B). The photoacid generating agent (B) is not particularly limited as long as it is a compound directly or indirectly generating an acid with light. Examples of the photoacid generating agent (B) include a first to fifth photoacid generators as described below.

### (First Photoacid Generating Agent)

A first photoacid generating agent may be a compound represented by Formula (b1) below:

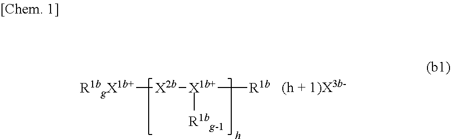

In Formula (b1) above, X^{1b} represents a sulfur atom or an iodine atom having a valency of g, and g is 1 or 2. h is a number of repetitions of a building block in brackets and represents an integer 0 or more. R^{1b} is an organic group attached to X^{1b} and represents an aryl group having 6 or more and 30 or less carbon atoms, a heterocyclic group having 4 or more and 30 or less carbon atoms, an alkyl group having 1 or more and 30 or less carbon atoms, an alkenyl group having 2 or more and 30 or less carbon atoms, or an alkynyl group having 2 or more and 30 or less carbon atoms, and R^{1b} may be substituted with at least one selected from the group consisting of an alkyl group, a hydroxy group, an alkoxy group, an alkylcarbonyl group, an arylcarbonyl group, an alkoxycarbonyl group, an aryloxycarbonyl group, an arylthiocarbonyl group, an acyloxy group, an arylthio group, an alkylthio group, an aryl group, a heterocyclic group, an aryloxy group, an alkylsulfinyl group, an arylsulfinyl group, an alkylsulfonyl group, an arylsulfonyl group, an alkyleneoxy group, an amino group, a cyano group, a nitro group, and a halogen. A number of R^{1b} is g+h (g−1)+1, and R^{1b} may be the same as or different from each other. Furthermore, two or more R^{1b} can be attached to each other directly or via —O—, —S—, —SO—, —SO₂—, —NH—, —NR^{2b}—, —CO—, —COO—, —CONH—, an alkylene group having 1 or more and 3 or less carbon atoms, or a phenylene group to form a ring structure including X^{1b}. R^{2b} is an alkyl group having 1 or more and 5 or less carbon atoms or an aryl group having 6 or more and 10 or less carbon atoms.

X²¹ is a group represented by Formula (b2) below:

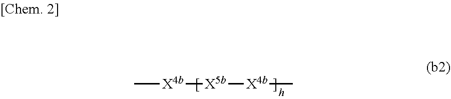

In Formula (b2) above, X⁴b represents an alkylene group having 1 or more and 8 or less carbon atoms, an arylene group having 6 or more and 20 or less carbon atoms, or a divalent group of a heterocyclic compound having 8 or more and 20 or less carbon atoms, and X^{4b} may be substituted with at least one selected from the group consisting of an alkyl group having 1 or more and 8 or less carbon atoms, an alkoxy group having 1 or more and 8 or less carbon atoms, an aryl group having 6 or more and 10 or less carbon atoms, a hydroxy group, a cyano group, a nitro group, and a halogen. X^{5b} is —O—, —S—, —SO—, —SO₂—, —NH—, —NR^{2b}—, —CO—, —COO—, —CONH—, an alkylene group having 1 or more and 3 or less carbon atoms, or a phenylene group. h represents a number of repetitions of a building block in brackets. h+1 X^{4b}s and h R^{5b}s may be the same as or different from each other. R^{2b} is the same as the above-mentioned definition.

X^{3b-} is an onium counterion, and examples thereof include a fluorinated alkyl fluorophosphate anion represented by Formula (b9), (b13), (b14), or (b17) below or a borate anion represented by Formula (b18) below.

[Chem. 3]

R^{20b}SO₃ (b9)

In Formula (b9) above, R^{20b} is a group represented by Formula (b10), (b11), or (b12) below.

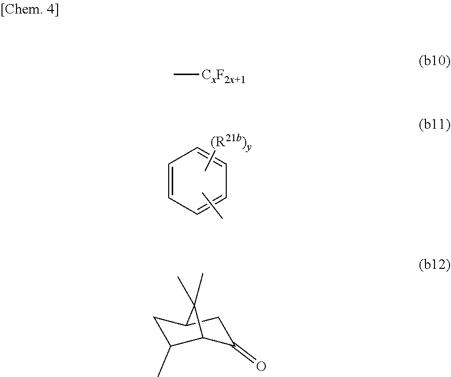

In Formula (b10) above, x represents an integer of 1 or more and 4 or less. In Formula (b11) above, R^{21b} represents a hydrogen atom, a hydroxy group, a linear or branched alkyl group having 1 or more and 6 or less carbon atoms, or a linear or branched alkoxy group having 1 or more and 6 or less carbon atoms, and y represents an integer of 1 or more and 3 or less. Among these, trifluoromethanesulfonte or perfluorobutanesulfonate is preferred from the viewpoint of safety.

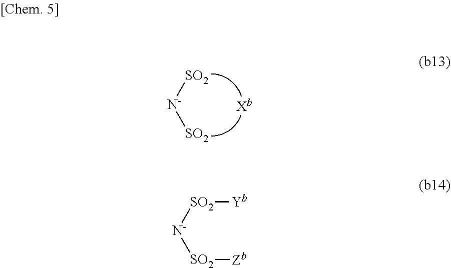

In Formula (b13) or (b14) above, X^{b} represents a linear or branched alkylene group in which at least one hydrogen atom is substituted with a fluorine atom and the alkylene group has 2 or more and 6 or less carbon atoms, preferably 3 or more and 5 or less carbon atoms, and most preferably 3 carbon atoms. Y^{b} and Z^{b} each independently represent a linear or branched alkyl group in which at least one hydrogen atom is substituted with a fluorine atom, and the alkyl group has 1 or more and 10 or less carbon atoms, preferably 1 or more and 7 or less carbon atoms, and more preferably 1 or more and 3 or less carbon atoms.

A smaller number of carbon atoms in the alkylene group for X^{b} or the alkyl group for Y^{b} or Z^{b} is preferred because of better solubility in an organic solvent.

Furthermore, a larger number of hydrogen atoms substituted with a fluorine atom in the alkylene group for X^{b} or the alkyl group for Y^{b} or Z^{b} is preferred because of a stronger acid strength. A percentage of fluorine atoms in the alkylene group or the alkyl group, i.e., a fluorination rate is preferably 70% or more and 100% or less and more preferably 90% or more and 100% or less, and a perfluoroalkylene group or a perfluoroalkyl group in which all hydrogen atoms are substituted with a fluorine atom is most preferred.

[Chem. 6]

[(R^{3b})ⱼPF₆₋ⱼ]⁻ (b17)

In Formula (b17) above, R^{3b} represents an alkyl group in which 80% or more of hydrogen atoms are substituted with a fluorine atom. j denotes a number of R^{3b} and is an integer of 1 or more and 5 or less. j R^{3b}s may be the same as or different from each other.

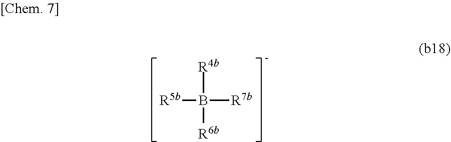

In Formula (b18) above, R^{4b} to R^{7b} each independently represents a fluorine atom or a phenyl group, and a part or all of hydrogen atoms in the phenyl group may be substituted with at least one selected from the group consisting of a fluorine atom and a trifluoromethyl group.

Examples of an onium ion in a compound represented by Formula (b1) above include triphenylsulfonium, tri-p-tolylsulfonium, 4-(phenylthio)phenyldiphenylsulfonium, bis[4-(diphenylsulfonio)phenyl]sulfide, bis[4-{bis[4-(2-hydroxyethoxy)phenyl]sulfonio}phenyl]sulfide, bis{4-[bis(4-fluorophenyl)sulfonio]phenyl]sulfide, 4-(4-benzoyl-2-chlorophenylthio)phenylbis(4-fluorophenyl)sulfonium, 7-isopropyl-9-oxo-10-thia-9,10-dihydroanthracen-2-yldi-p-tolylsulfonium, 7-isopropyl-9-oxo-10-thia-9,10-dihydroanthracen-2-yldiphenylsulfonium, 2-[(diphenyl)sulfonio]thioxanthone, 4-[4-(4-tert-butylbenzoyl)phenylthio]phenyldi-p-tolylsulfonium, 4-(4-benzoylphenylthio)phenyldiphenylsulfonium, diphenylphenacylsulfonium, 4-hydroxyphenylmethylbenzylsulfonium, 2-naphthylmethyl(1-ethoxycarbonyl)ethylsulfonium, 4-hydroxyphenylmethylphenacylsulfonium, phenyl[4-(4-biphenylthio)phenyl]4-biphenylsulfonium, phenyl[4-(4-biphenylthio)phenyl]3-biphenylsulfonium, [4-(4-acetophenylthio)phenyl]diphenylsulfonium, octadecylmethylphenacylsulfonium, diphenyliodonium, di-p-tolyliodonium, bis(4-dodecylphenyl)iodonium, bis(4-methoxyphenyl)iodonium, (4-octyloxyphenyl)phenyliodonium, bis(4-decyloxy)phenyliodonium, 4-(2-hydroxytetradecyloxy)phenylphenyliodonium, 4-isopropylphenyl(p-tolyl)iodonium, or 4-isobutylphenyl(p-tolyl)iodonium, etc.

In a fluorinated alkyl fluorophosphate anion represented by Formula (b17) above, R^{3b} represents an alkyl group substituted with a fluorine atom and preferably has 1 or more and 8 or less carbon atoms and further preferably 1 or more and 4 or less carbon atoms. Specific examples of the alkyl group include a linear alkyl group such as a methyl group, an ethyl group, a propyl group, a butyl group, a pentyl group, or an octyl; a branched alkyl group such as an isopropyl group, an isobutyl group, a sec-butyl, or a tert-butyl group; or a cycloalkyl group such as a cyclopropyl group, a cyclobutyl group, a cyclopentyl group, or a cyclohexyl group, etc. A percentage of hydrogen atoms substituted with a fluorine atom in the alkyl group is usually 80% or more, preferably 90% or more, and further preferably 100%. If a substitution rate with a fluorine atom is less than 80%, an acid strength of an onium fluorinated alkyl fluorophosphate represented by Formula (b1) above decreases.

R^{3b} is particularly preferably a linear or branched perfluoroalkyl group having 1 or more and 4 or less carbon atoms and 100% of the substitution rate with a fluorine atom, and specific examples thereof include CF₃, CF₃CF₂, (CF₃)₂CF, CF₃CF₂CF₂, CF₃CF₂CF₂CF₂, (CF₃)₂CFCF₂, CF₃CF₂ (CF₃) CF, (CF₃)₃C, etc. A number of R^{3b}, j, is an integer of 1 or more and 5 or less, preferably 2 or more and 4 or less, and particularly preferably 2 or 3.

Specific preferred examples of the fluorinated alkyl fluorophosphate anion include [(CF₃CF₂)₂PF₄]⁻, [(CF₃CF₂)₃PF₃]⁻, [((CF₃)₂CF)₂PF₄]⁻, [((CF₃)₂CF)₃PF₃]⁻, [(CF₃CF₂CF₂)₂PF₄]⁻, [(CF₃CF₂CF₂)₃PF₃]⁻, [((CF₃)₂CFCF₂)₂PF₄]⁻, [((CF₃)₂CFCF₂)₃PF₃]⁻, [(CF₃CF₂CF₂CF₂)₂PF₄]⁻, or [(CF₃CF₂CF₂)₃PF₃]⁻. Among these, [(CF₃CF₂)₃PF₃]⁻, [(CF₃CF₂CF₂)₃PF₃]⁻, [((CF₃)₂CF)₃PF₃]⁻, [((CF₃)₂CF)₂PF₄]⁻, [((CF₃)₂CFCF₂)₃PF₃]⁻, or [((CF₃)₂CFCF₂)₂PF₄]⁻ is particularly preferred.

Specific preferred examples of the borate anion represented by Formula (b18) above include tetrakis(pentafluorophenyl)borate ([B(C₆F₅)₄]⁻), tetrakis[(trifluoromethyl)phenyl]borate ([B(C₆H₄CF₃)₄]⁻), difluorobis(pentafluorophenyl) borate ([(C₆F₅)₂BF₂]⁻), trifluoro (pentafluorophenyl)borate ([(C₆F₅)BF₃]⁻), tetrakis(difluorophenyl)borate ({B(C₆H₃F₂)₄⁻), etc. Among these, tetrakis(pentafluorophenyl)borate ([B(C₆F₅)₄]⁻) is particularly preferred.

### (Second Photoacid Generating Agent)

Examples of a second photoacid generating agent include a halogen-containing triazine compound such as 2,4-bis(trichloromethyl)-6-piperonyl-1,3,5-triazine, 2,4-bis(trichloromethyl)-6-[2-(2-furyl)ethenyl]-s-triazine, 2,4-bis(trichloromethyl)-6-[2-(5-methyl-2-furyl)ethenyl]-s-triazine, 2,4-bis(trichloromethyl)-6-[2-(5-ethyl-2-furyl)ethenyl]-s-triazine, 2,4-bis(trichloromethyl)-6-[2-(5-propyl-2-furyl)ethenyl]-s-triazine, 2,4-bis(trichloromethyl)-6-[2-(3,5-dimethoxyphenyl)ethenyl]-s-triazine, 2,4-bis(trichloromethyl)-6-[2-(3,5-diethoxyphenyl)ethenyl]-s-triazine, 2,4-bis(trichloromethyl)-6-[2-(3,5-dipropoxyphenyl)ethenyl]-s-triazine, 2,4-bis(trichloromethyl)-6-[2-(3-methoxy-5-ethoxyphenyl)ethenyl]-s-triazine, 2,4-bis(trichloromethyl)-6-[2-(3-methoxy-5-propoxyphenyl)ethenyl]-s-triazine, 2,4-bis(trichloromethyl)-6-[2-(3,4-methylenedioxyphenyl)ethenyl-s-triazine, 2,4-bis-(trichloromethyl)-6-(3,4-methylenedioxyphenyl)-s-triazine, 2,4-bis-trichloromethyl-6-(3-bromo-4-methoxy)phenyl-s-triazine, 2,4-bis-trichloromethyl-6-(2-bromo-4-methoxy)phenyl-s-triazine, 2,4-bis-trichloromethyl-6-(2-bromo-4-methoby)styrylphenyl-s-triazine, 2,4-bis-trichloromethyl-6-(3-bromo-4-methoxy)styrylphenyl-s-triazine, 2-(4-methoxyphenyl)-4,6-bis(trichloromethyl)-1,3,5-triazine, 2-(4-methoxynaphthyl)-4,6-bis(trichloromethyl)-1,3,5-triazine, 2-[2-(2-furyl)ethenyl]-4,6-bis(trichloromethyl)-1,3,5-triazine, 2-[2-(5-methyl-2-furyl)ethenyl]-4,6-bis(trichloromethyl)-1,3,5-triazine, 2-[2-(3,5-dimethoxyphenyl)ethenyl]-4,6-bis(trichloromethyl)-1,3,5-triazine, 2-[2-(3,4-dimethoxyphenyl)ethenyl]-4,6-bis(trichloromethyl)-1,3,5-triazine, 2-(3,4-methylenedioxyphenyl)-4,6-bis(trichloromethyl)-1,3,5-triazine, tris(1,3-dibromopropyl)-1,3,5-triazine, or tris(2,3-dibromopropyl)-1,3,5-triazine, or a halogen-containing triazine compound represented by Formula (b3) below such as tris(2,3-dibromopropyl)isocyanurate, etc.

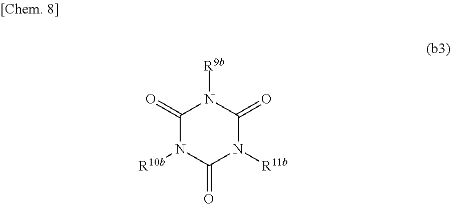

In Formula (b3) above, R^{9b}, R^{10b}, and R^{11b} each independently represent a halogenated alkyl group.

### (Third Photoacid Generating Agent)

Examples of a third photoacid generating agent include α-(p-toluenesulfonyloxyimino)-phenylacetonitrile, α-(benzenesulfonyloxyimino)-2,4-dichlorophenylacetonitrile, α-(benzenesulfonyloxyimino)-2,6-dichlorophenylacetonitrile, α-(2-chlorobenzenesulfonyloxyimino)-4-methoxyphenylacetonitrile, α-(ethylsulfonyloxyimino)-1-cyclopentenylacetonitrile, or a compound represented by Formula (b4) below and containing an oximesulfonate group.

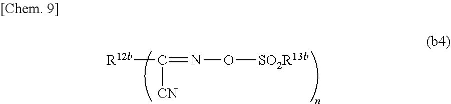

In Formula (b4) above, R^{12b} represents a monovalent, divalent, or trivalent organic group, R^{13b} represents a substituted or unsubstituted saturated hydrocarbon group, an unsaturated hydrocarbon group, or an aromatic group, and n represents a number of repetitions of a building block in parentheses.

In Formula (b4) above, an aromatic group may be an aryl group such as a phenyl group or a naphthyl group, a heteroaryl group such as a furyl group or a thienyl group, etc. The aromatic group may have one or more suitable substituents on a ring, such as a halogen atom, an alkyl group, an alkoxy group, a nitro group, etc. Furthermore, R^{13b} is particularly preferably an alkyl group having 1 or more and 6 or less carbon atoms such as a methyl group, an ethyl group, an n-propyl group, or a butyl group. In particular, a compound in which R^{12b} is an aromatic group and R^{13b} is an alkyl group having 1 or more and 4 or less carbon atoms is preferred.

When n=1, a photoacid generating agent represented by Formula (b4) above may be a compound in which R^{12b} is a phenyl group, a methylphenyl group, or a methoxyphenyl group and R^{13b} is a methyl group, specifically, α-(methylsulfonyloxyimino)-1-phenylacetonitrile, α-(methylsulfonyloxyimino)-1-(p-methylphenyl)acetonitrile, α-(methylsulfonyloxyimino)-1-(p-methoxyphenyl)acetonitrile, [2-(propylsulfonyloxyimino)-2,3-dihydroxythiophen-3-ylidene](o-tolyl)acetonitrile, etc. When n=2, the photoacid generating agent represented by the Formula (b4) above may be specifically a photoacid generating agent represented by any of Formulae below.

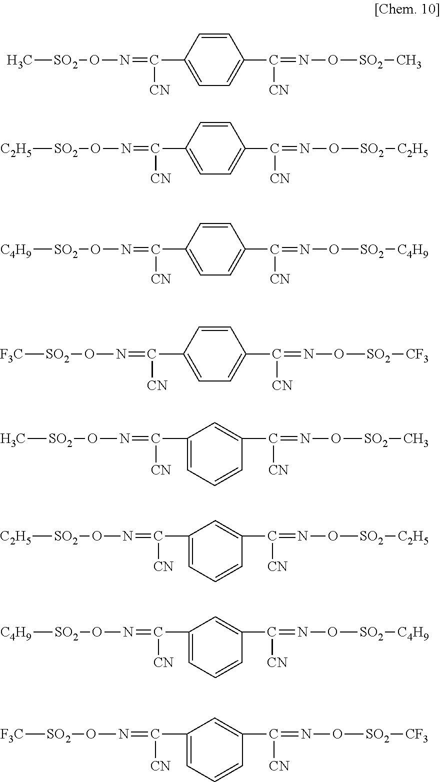

### (Fourth Photoacid Generating Agent)

Examples of a fourth photoacid generating agent include bisulfonyldiazomethane such as bis(p-toluenesulfonyl)diazomethane, bis(1,1-dimethylethylsulfonyl)diazomethane, bis(cyclohexylsulfonyl)diazomethane, or bis(2,4-dimethylphenylsulfonyl)diazomethane; a nitrobenzyl derivative such as 2-nitrobenzyl p-toluenesulfonate, 2,6-dinitrobenzyl p-toluenesulfonate, nitrobenzyl tosylate, dinitrobenzyl tosylate, nitrobenzyl sulfonate, nitrobenzyl carbonate, or dinitrobenzyl carbonate; a sulfonic ester such as pyrogallol trimesylate, pyrogallol tritosylate, benzyl tosylate, benzyl sulfonate, N-methylsulfonyloxysuccinimide, N-trichloromethylsulfonyloxysuccinimide, N-phenylsulfonyloxymaleimide, or N-methylsulfonyloxyphthalimide; trifluoromethanesulfonic ester such as N-(trifluoromethylsulfonyloxy)phthalimide, N-(trifluoromethylsulfonyloxy)-1,8-phthalimide, or N-(trifluoromethylsulfonyloxy)-4-butyl-1,8-naphthalimide; an onium salt such as diphenyliodonium hexafluorophosphate, (4-methoxyphenyl)phenyliodonium trifluoromethanesulfonate, bis(p-tert-butylphenyl)iodonium trifluoromethanesulfonate, triphenylsulfonium hexafluorophosphate, (4-methoxyphenyl)diphenylsulfonium trifluoromethanesulfonate, or (p-tert-(butylphenyl)diphenylsulfonium trifluoromethanesulfonate; a benzoin tosylate such as benzoin tosylate or α-methylbenzoin tosylate; another diphenyliodonium salt, triphenylsulfonium salt, phenyldiazonium salt, benzylcarbonate, etc.

### (Fifth Photoacid Generating Agent)

A fifth photoacid generating agent may be a compound (B0) represented by Formula (B0) below (hereinafter also referred to as “(B0) component”):

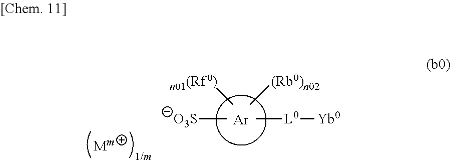

in which Ar represents an aromatic ring; Rf⁰ represents a fluorinated alkyl group having 1 or more and 5 or less carbon atoms or a fluorine atom; L⁰ represents a divalent linking group including —C(═O)—O—, —O—C(═O)—, or —O—S(═O)₂—; Yb⁰ represents a cyclic group; Rb⁰ represents an organic group; n01 is an integer from 1 or more as long as a valency is acceptable; n02 is an integer from 0 or more as long as a valency is acceptable; provided that, when L⁰-Yb⁰ is —O—C(═O)—Yb⁰, Yb⁰ is an optionally substituted alicyclic group, an optionally substituted fused ring group of an aliphatic ring and an aromatic ring, or a substituted aromatic hydrocarbon group in which at least one hydrogen atom on an aromatic ring is substituted with an alkyl group or an alkoxy group; when n01 is 2 or more, a plurality of Rf⁰ may be the same as or different from each other; when n02 is 2 or more, a plurality of Rf⁰ may be the same as or different from each other; m is an integer of 1 or more; and M^{m+} represents an m-valent cation.

### {Anionic Moiety}

In Formula (b0) above, an aromatic ring for Ar is not particularly limited as long as it is a cyclic conjugated system with 4n+2 pi-electrons and may be monocyclic or polycyclic. The aromatic ring preferably has 5 or more and 30 or less carbon atoms, more preferably 5 or more and 20 or less carbon atoms, further preferably 6 or more and 15 or less carbon atoms, and particularly preferably 6 or more and 12 or less carbon atoms. Specific examples of the aromatic ring include an aromatic hydrocarbon ring such as benzene, naphthalene, anthracene, or phenanthrene; an aromatic heterocyclic ring in which a part of carbon atoms constituting the aromatic hydrocarbon ring is substituted with a heteroatom; etc. Examples of the heteroatom in the aromatic hydrocarbon ring include an oxygen atom, a sulfur atom, a nitrogen atom, etc. Specific examples of the aromatic heterocyclic ring include a pyridine ring, a thiophene ring, a furan ring, etc.

The aromatic ring for Ar is preferably an aromatic hydrocarbon ring, more preferably a benzene ring or a naphthalene ring, and further preferably a benzene ring.

In Formula (b0) above, a fluorinated alkyl group having 1 or more and 5 or less carbon atoms for Rf⁰ is a group in which a part or all of hydrogen atoms in an alkyl group having 1 or more and 5 or less carbon atoms are substituted with a fluorine atom. The fluorinated alkyl group may be linear or branched, and is preferably linear. A linear fluorinated alkyl group for Rf⁰ preferably has 1 or more and 3 or less carbon atoms, more preferably 1 or 2 carbon atoms, and further preferably 1 carbon atom. A branched fluorinated alkyl group for Rf⁰ preferably has 3 or 4 carbon atoms and more preferably 3 carbon atoms. The fluorinated alkyl group having 1 or more and 5 or less carbon atoms for Rf⁰ is preferably a perfluoroalkyl group and more preferably a trifluoromethyl group from the viewpoint of acid strength.

Rf⁰ is preferably a fluorine atom or a trifluoromethyl group and more preferably a fluorine atom from the viewpoint of acid strength.

In Formula (b0) above, an organic group for Rb⁰ is a hydrocarbon group that may have a substituent. The hydrocarbon group may be an aliphatic hydrocarbon group or an aromatic hydrocarbon group, and preferably an aliphatic hydrocarbon group.

The aliphatic hydrocarbon group for Rb⁰ preferably has 1 or more and 10 or less carbon atoms, more preferably 1 or more and 6 or less carbon atoms, further preferably 1 or more and 4 or less carbon atoms, and particularly preferably 1 or more and 3 or less carbon atoms. The aliphatic hydrocarbon group for Rb⁰ may be saturated or unsaturated, and is preferably saturated. The aliphatic hydrocarbon group for Rb⁰ is preferably a linear or branched alkyl group.

A linear alkyl group for Rb⁰ preferably has 1 or more and 3 or less carbon atoms, more preferably 1 or 2 carbon atoms, and further preferably 1 carbon atom. A branched alkyl group for Rb⁰ preferably has 3 or 4 carbon atoms and more preferably 3 carbon atoms. An organic group for Rb⁰ is preferably a linear or branched alkyl group having 1 or more and 5 or less carbon atoms, more preferably a linear or branched alkyl group having 1 or more and 3 or less carbon atoms, and further preferably an ethyl group or a methyl group.

In Formula (b0) above, n01 is an integer from 1 or more as long as a valency is acceptable. n01 is preferably 1 or more and 4 or less, more preferably 2 or more and 4 or less, further preferably 3 or 4, and particularly preferably 4.

In Formula (b0) above, n02 is an integer from 0 or more as long as a valency is acceptable. n02 is preferably 0 or more and 3 or less, more preferably 0 or more and 2 or less, further preferably 0 or 1, and most preferably 0.

In Formula (b0) above, a divalent linking group for L⁰ may be —C(═O)—O—, —O—C(═O)—, —O—S(═O)₂—, a combination of one or more thereof and an alkylene group, etc. When the divalent linking group for L⁰ is —C(═O)—O—, —O—C(═O)—, or —O—S(═O)₂—, L⁰-Yb⁰ is —C(═O)—O—Yb⁰, —O—C(═O)—Yb⁰, or —O—S(═O)₂—Yb⁰. When L⁰ is the combination of one or more of —C(═O)—O—, —O—C(═O)O—, or —O—S(═O)₂— and an alkylene group, the alkylene group may be linear or branched.

Examples of the divalent linking group for L⁰ include a linking group represented by General formula (L0-1) below:

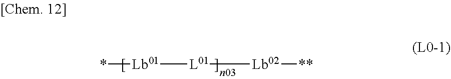

in which Lb⁰¹ and Lb⁰² each independently represent a single bond or an alkylene group having 1 or more and 5 or less carbon atoms; L⁰¹ is —C(═O)—O—, —O—C(═O)—, or —O—S(═O)₂—; n03 represents an integer of 1 or more and 3 or less; provided that, when n03 is 2 or 3, Lb⁰¹ cannot be a single bond; when n03 is 2 or 3, a plurality of Lb⁰¹ may be the same as or different from each other; when n03 is 2 or more, a plurality of L⁰¹ may be the same as or different from each other; * is an atomic bond to Ar in Formula (b0) above, and ** is an atomic bond to Yb⁰ in Formula (b0) above.

In Formula (L0-1) above, an alkylene group having 1 or more and 5 or less carbon atoms for Lb⁰¹ and Lb⁰² may be linear or branched, and is preferably linear. A linear alkylene group for Lb⁰¹ and Lb⁰² preferably has 1 or more and 3 or less carbon atoms and more preferably 1 or 2 carbon atoms. A branched alkylene group for Lb⁰¹ and Lb⁰² preferably has 2 or more and 4 or less carbon atoms and more preferably 2 or 3 carbon atoms.

In Formula (L0-1) above, n03 is preferably 1 or 2 and more preferably 1.

Examples of the divalent linking group for L⁰ include a linking group represented by any of General formulae (L01-1) to (L01-3) below:

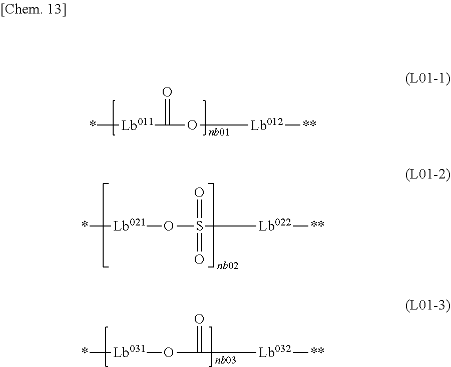

in which Lb⁰¹¹ to Lb⁰³¹ each independently represent a single bond or an alkylene group having 1 or more and 5 or less carbon atoms; Lb⁰¹² to Lb⁰³² each independently represent a single bond or a divalent linking group; nb01 to nb03 each independently represent an integer of 1 or more and 3 or less; provided that, when nb01 to nb03 is 2 or 3, Lb⁰¹¹ to LB⁰³¹ cannot be a single bond; when nb01 is 2 or 3, a plurality of Lb⁰¹¹ may be the same as or different from each other; when nb02 is 2 or 3, a plurality of Lb⁰²¹ may be the same as or different from each other; when nb03 is 2 or 3, a plurality of Lb⁰³¹ may be the same as or different from each other; * represents an atomic bond to Ar in General formula (b0) above, and ** represents an atomic bond to Yb⁰ in General formula (b0) above.

In Formulae (L01-1) to (L01-3) above, an alkylene group having 1 or more and 5 or less carbon atoms for Lb⁰¹¹ to Lb⁰³¹ may be the same as Lb⁰¹ in Formula (L0-1) above. In Formulae (L01-1) to (L01-3) above, a divalent linking group for Lb⁰¹² to Lb⁰³² may be an alkylene group that has 1 or more and 5 or less carbon atoms and that may have —C(═O)—O—, —O—C(═O)—, or —O—S(═O)₂—. The alkylene group having 1 or more and 5 or less carbon atoms may be the same as Lb⁰¹ in Formula (L0-1) above. In Formulae (L01-1) to (L01-3), nb01 to nb03 is preferably 1 or 2 and more preferably 1.

Examples of L⁰ in Formula (b0) above include a group represented by any of General formulae (L0-1-1) to (L0-1-5) below:

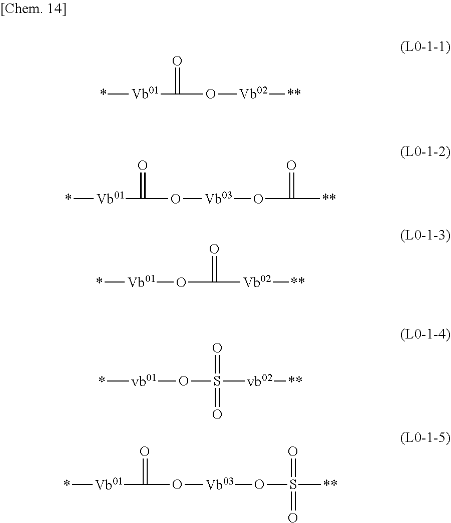

in which Vb⁰¹ and Vb⁰² each independently represent a single bond or an alkylene group having 1 or more and 5 or less carbon atoms; Vb⁰³ represents an alkylene group having 1 or more and 5 or less carbon atoms; * is an atomic bond to Ar in Formula (b0) above, and ** is an atomic bond to Yb⁰ in Formula (b0) above.

In Formulae (L0-1-1) to (L0-1-5), an alkylene group having 1 or more and 5 or less carbon atoms for Vb⁰¹ and Vb⁰² may be linear or branched, and is preferably linear. A linear alkylene group for Vb⁰¹ and Vb⁰² preferably has 1 or more and 3 or less carbon atoms and more preferably 1 or 2 carbon atoms. A branched alkylene group for Vb⁰¹ and Vb⁰² preferably has 2 or more and 4 or less carbon atoms and more preferably 2 or 3 carbon atoms.

### <<Yb⁰>>

The case where L⁰-Yb⁰ is not —O—C(═O)—Yb⁰: when L⁰-Yb⁰ is not —O—C(═O)—Yb⁰, Yb⁰ is a cyclic group. The cyclic group for Yb⁰ is preferably a cyclic hydrocarbon group. The cyclic hydrocarbon group may be an aromatic hydrocarbon group or an aliphatic hydrocarbon group. The aliphatic hydrocarbon group is preferably saturated.

An aromatic hydrocarbon group for Yb⁰ is a hydrocarbon group having an aromatic ring. A number of carbon atoms in the aromatic hydrocarbon group is preferably 3 or more and 30 or less, more preferably 5 or more and 30 or less, further preferably 5 or more and 20 or less, particularly preferably 6 or more and 15 or less, and most preferably 6 or more and 10 or less, provided that, the number of carbon atoms shall not include a number of carbon atoms in a substituent. Specific examples of an aromatic ring that the aromatic hydrocarbon group for Yb⁰ has include benzene, fluorene, naphthalene, anthracene, phenanthrene, biphenyl, or an aromatic heterocyclic ring in which a part of carbon atoms constituting the aromatic ring is substituted with a heteroatom; etc. Examples of the heteroatom in the aromatic hydrocarbon ring include an oxygen atom, a sulfur atom, a nitrogen atom, etc. Specific examples of the aromatic hydrocarbon group for Yb⁰ include a group in which one hydrogen atom is removed from the aromatic ring (an aryl group: e.g., a phenyl group, a naphthyl group, etc.), a group in which one hydrogen atom in the aromatic ring is substituted with an alkylene group (e.g., a benzyl group, a phenethyl group, a 1-naphthylmethyl group, etc.), etc. The alkylene group (an alkyl chain in the arylalkyl group) has preferably 1 or more and 4 or less carbon atoms, more preferably 1 or 2 carbon atoms, and particularly preferably 1 carbon atom.

A cyclic aliphatic hydrocarbon group for Yb⁰ may be an aliphatic hydrocarbon group including a ring in its structure. Examples of the aliphatic hydrocarbon group including a ring in its structure include an alicyclic hydrocarbon group (a group in which one hydrogen atom is removed from an aliphatic hydrocarbon ring), a group in which an alicyclic hydrocarbon group is attached to an end of a linear- or branched-aliphatic hydrocarbon group, a group in which a linear- or branched-aliphatic hydrocarbon group is interrupted by an alicyclic hydrocarbon group, etc. The alicyclic hydrocarbon group preferably has 3 or more and 20 or less carbon atoms and more preferably 3 or more and 12 or less carbon atoms. The alicyclic hydrocarbon group may be a polycyclic group or a monocyclic group. A monocyclic alicyclic hydrocarbon group is preferably a group in which one or more hydrogen atoms are removed from a monocycloalkane. The monocycloalkane preferably has 3 or more and 6 or less carbon atoms and specific examples thereof include cyclopentane, cyclohexane, etc. A polycyclic alicyclic hydrocarbon group is preferably a group in which one or more hydrogen atoms are removed from a polycycloalkane, and the polycycloalkane preferably has 7 or more and 30 or less carbon atoms. Among these, the polycycloalkane is preferably a polycycloalkane having a polycyclic skeleton of a bridge ring system such as adamantane, norbornane, isobornane, bornane, tricyclodecane, or tetracyclododecane; a polycycloalkane having a polycyclic skeleton of a fused ring system such as a cyclic group having a steroid skeleton.

A cyclic aliphatic hydrocarbon group for Yb⁰ is preferably a group in which one or more hydrogen atoms are removed from a monocycloalkane or a polycycloalkane, more preferably a group in which one hydrogen atom is removed from a polycycloalkane, further preferably an adamantyl group, a norbornyl group, or a bornyl group, and particularly preferably an adamantyl group.

A linear aliphatic hydrocarbon group that may be attached to an alicyclic hydrocarbon group preferably has 1 or more and 10 or less carbon atoms, more preferably 1 or more and 6 or less carbon atoms, further preferably 1 or more and 4 or less carbon atoms, and most preferably 1 or more and 3 or less carbon atoms. The linear aliphatic hydrocarbon group is preferably a linear alkylene group, specifically, a methylene group [—CH₂—], an ethylene group [—(CH₂)₂—], a trimethylene group [—(CH₂)₃—], a tetramethylene group [—(CH₂)₄—], a pentamethylene group [—(CH₂)₅—], etc. A branched aliphatic hydrocarbon group that may be attached to an alicyclic hydrocarbon group preferably has 2 or more and 10 or less carbon atoms, more preferably 3 or more and 6 or less carbon atoms, further preferably 3 or 4, and most preferably 3 carbon atoms. The branched aliphatic hydrocarbon group is preferably a branched alkylene group, specifically, an alkylalkylene group, for example, an alkylmethylene group such as —CH(CH₃)—, —CH(CH₂CH₃)—, —C(CH₃)₂—, —C(CH₃) (CH₂CH₃)—, —C(CH₃) (CH₂CH₂CH₃)—, or —C(CH₂CH₃)₂—; an alkylethylene group such as —CH(CH₃) CH₂—, —CH(CH₃) CH(CH₃)—, —C(CH₃)₂CH₂—, —CH(CH₂CH₃) CH₂—, or —C(CH₂CH₃)₂—CH₂—; an alkyltrimethylene group such as —CH(CH₃) CH₂CH₂— or —CH₂CH(CH₃)CH₂—; or an alkyltetramethylene group such as —CH(CH₃) CH₂CH₂CH₂— or —CH₂CH(CH₃) CH₂CH₂—, etc. An alkyl group in the alkylalkylene group is preferably a linear alkyl group having 1 or more and 5 or less carbon atoms.

A cyclic hydrocarbon group for Yb⁰ may include a heteroatom like a heterocycle. Specific examples thereof include a lactone-containing cyclic group represented by each of General formula (a2-r-1) to (a2-r-7) below, a —SO₂— containing cyclic group represented by each of General formula (b5-r-1) to (b5-r-4) below, a heterocyclic group represented by each of General formula (r-hr-1) to (r-hr-16) below, etc. In General formulae below, * represents an atomic bond to L⁰ in Formula (b0). Note that, as used herein, the phrase “lactone-containing cyclic group” refers to a cyclic group including a —O—C(═O)— containing ring (lactone ring) in its ring skeleton. When the lactone ring is counted as a first ring, the lactone-containing cyclic group is referred to as a monocyclic group if it has only the lactone ring, or as a polycyclic group if it has another ring structure regardless of its structure, The lactone-containing cyclic group may be a monocyclic group or a polycyclic group.

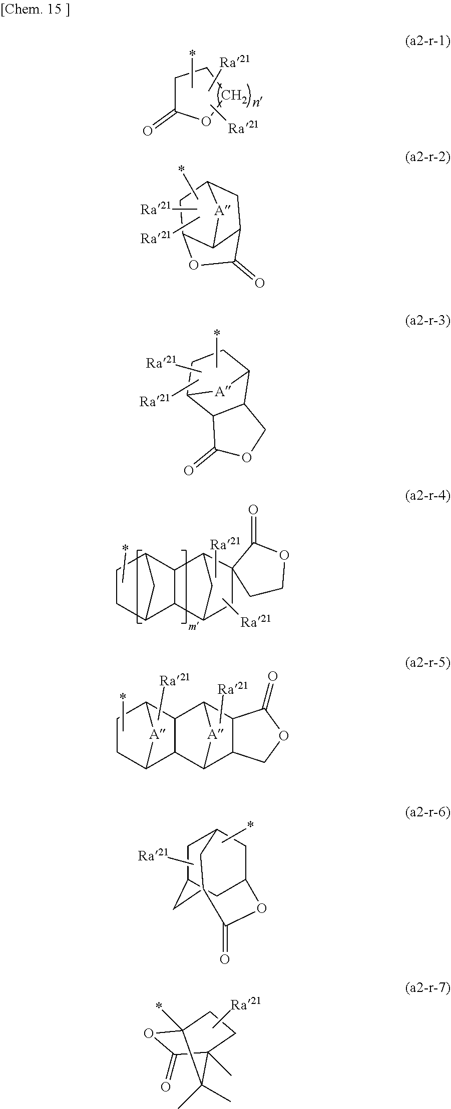

in which Ra′²¹ are each independently a hydrogen atom, an alkyl group, an alkoxy group, a halogen atom, a halogenated alkyl group, a hydroxy group, —COOR″, —OC(═O)R″, a hydroxyalkyl group, or a cyano group; R″ is a hydrogen atom, an alkyl group, or a lactone-containing cyclic group; A″ is an alkylene group having 1 or more and 5 or less carbon atoms and optionally containing an oxygen atom (—O—) or a sulfur atom (—S); n′ is an integer of 0 or more and 2 or less; m′ is 0 or 1; and * denotes an atomic bond, and so forth.

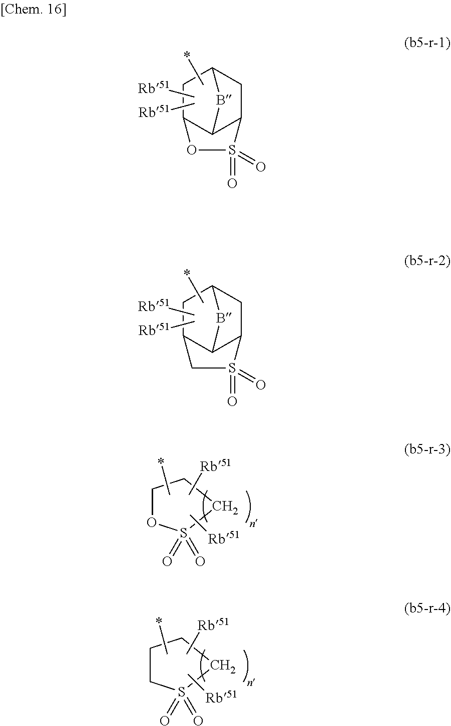

in which Ra′⁵¹ are each independently a hydrogen atom, an alkyl group, an alkoxy group, a halogen atom, a halogenated alkyl group, a hydroxy group, —COOR″, —OC(═O)R″, a hydroxyalkyl group, or a cyano group; R″ is a hydrogen atom, an alkyl group, a lactone-containing cyclic group, or a —SO₂— containing cyclic group; B″ is an alkylene group having 1 or more and 5 or less carbon atoms and optionally containing an oxygen atom or a sulfur atom; n′ is an integer of 0 or more and 2 or less; and * denotes an atomic bond.

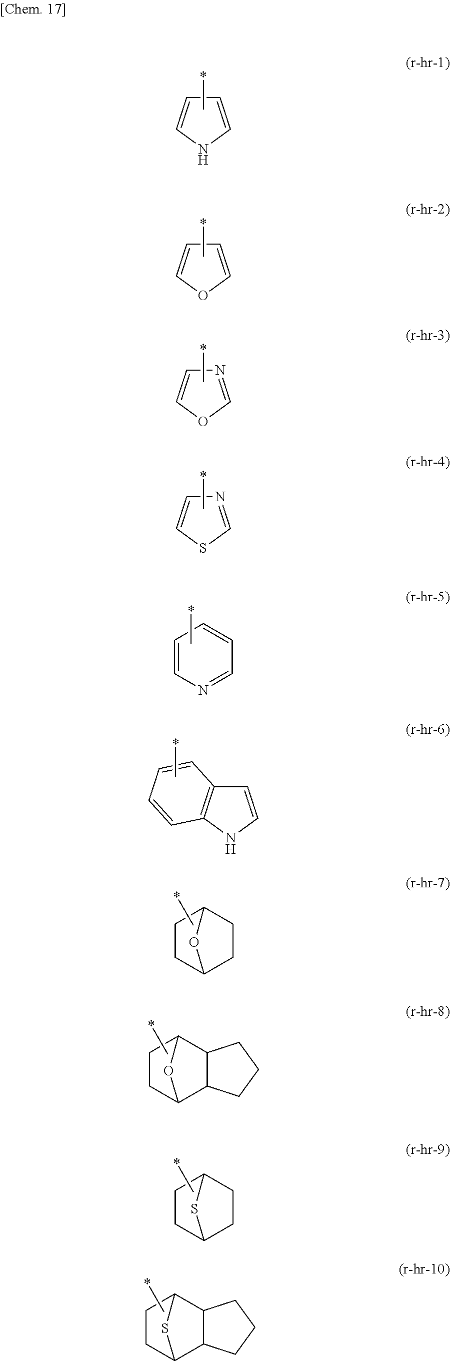

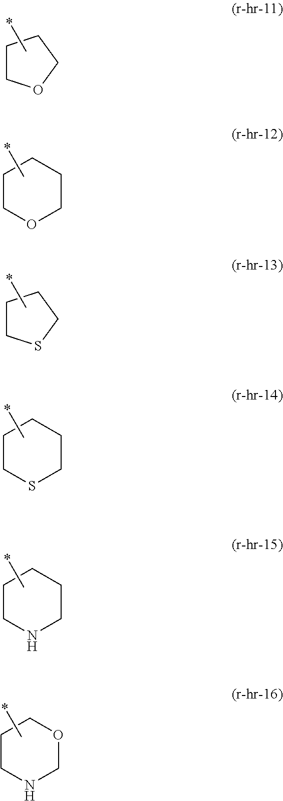

In General formula (a2-r-1) to (a2-r-7) above, an alkyl group for Ra′²¹ is preferably an alkyl group having 1 or more and 6 or less carbon atoms. The alkyl group is preferably linear or branched. Specific examples thereof include a methyl group, an ethyl group, a propyl group, an isopropyl group, an n-butyl group, an isobutyl group, a tert-butyl group, a pentyl group, an isopentyl group, a neopentyl group, a hexyl group, etc. Among these, a methyl group or an ethyl group is preferred, and a methyl group is particularly preferred. An alkoxy group for Ra′²¹ is preferably an alkoxy group having 1 or more and 6 or less carbon atoms. The alkoxyl group is preferably linear or branched. Specifically, the alkoxy group may be a group in which the alkyl group exemplified as the alkyl group for Ra′²¹ is linked to an oxygen atom (—O—). A halogen atom for Ra′²¹ is preferably a fluorine atom. A halogenated alkyl group for Ra′²¹ may be a group in which a part or all of hydrogen atoms in the alkyl group for Ra′²¹ are substituted with a halogen atom. The halogenated alkyl group is preferably a fluorinated alkyl group and particularly preferably a perfluoroalkyl group.

In —COOR″ or —OC(═O)R″ for Ra′²¹, R″ is, in each case, a hydrogen atom, an alkyl group, or a lactone-containing cyclic group. The alkyl group for R″ may be linear, branched, or cyclic and preferably has 1 or more and 15 or less carbon atoms. When R″ is a linear or branched alkyl group, it preferably has 1 or more and 10 or less carbon atoms, further preferably 1 or more and 5 or less carbon atoms, and particularly preferably is a methyl group or an ethyl group. When R″ is a cyclic alkyl group, it preferably has 3 or more and 15 or less carbon atoms, further preferably 4 or more and 12 or less carbon atoms, and most preferably 5 or more and 10 or less carbon atoms. Specific examples thereof include a group in which one or more hydrogen atoms are removed from a monocycloalkane which may or may not be substituted with a fluorine atom or a fluorinated alkyl group; a group in which one or more hydrogen atoms are removed from a polycycloalkane such as a bicycloalkane, a tricycloalkane, or a tetracycloalkane, etc. More specific examples thereof include a group in which one or more hydrogen atoms are removed from a monocycloalkane such as cyclopentane or cyclohexane; a group in which one or more hydrogen atoms are removed from a polycycloalkane such as adamantane, norbornane, isobornane, tricyclododecane, or tetracyclododecane, etc. A lactone-containing cyclic group for R″ may be the same as the group represented by each of General formulae (a2-r-1) to (a2-r-7) above. A hydroxy alkyl group for Ra′²¹ is preferably a hydroxy alkyl group having 1 or more and 6 or less carbon atoms, specifically, a group in which at least one of the hydrogen atoms in the alkyl group for Ra′²¹ is substituted with a hydroxy group.

Among these, Ra′²¹ are each independently preferably a hydrogen atom or a cyano group.

In General formulae (a2-r-2), (a2-r-3), and (a2-r-5) above, an alkylene group having 1 or more and 5 or less carbon atoms for A″ is preferably a linear or branched alkylene group and examples thereof include a methylene group, an ethylene group, an n-propylene group, an isopropylene group, etc. When the alkylene group includes an oxygen atom or a sulfur atom, specific examples thereof include a group in which —O— or —S— is present at an end or between carbon atoms of the alkylene group, e.g., —O—CH₂—, —CH₂—O—CH₂—, —S—CH₂—, —CH₂—S—CH₂—, etc. A″ is preferably an alkylene group having 1 or more and 5 or less carbon atoms or —O—, more preferably an alkylene group having 1 or more and 5 or less carbon atoms, and most preferably a methylene group.

Specific examples of a group represented by each of General formulae (a2-r-1) to (a2-r-7) will be shown below.

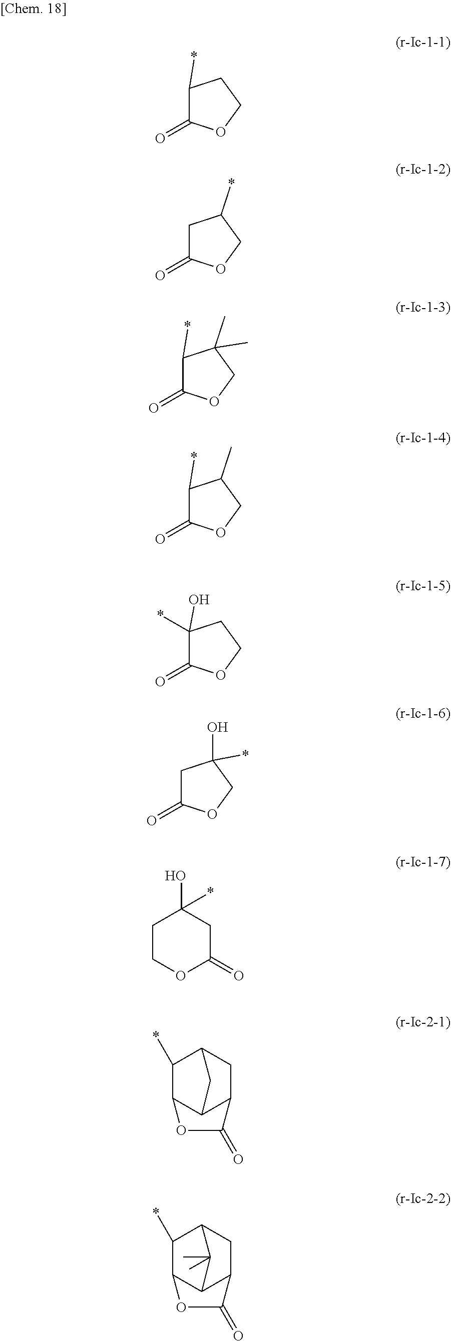

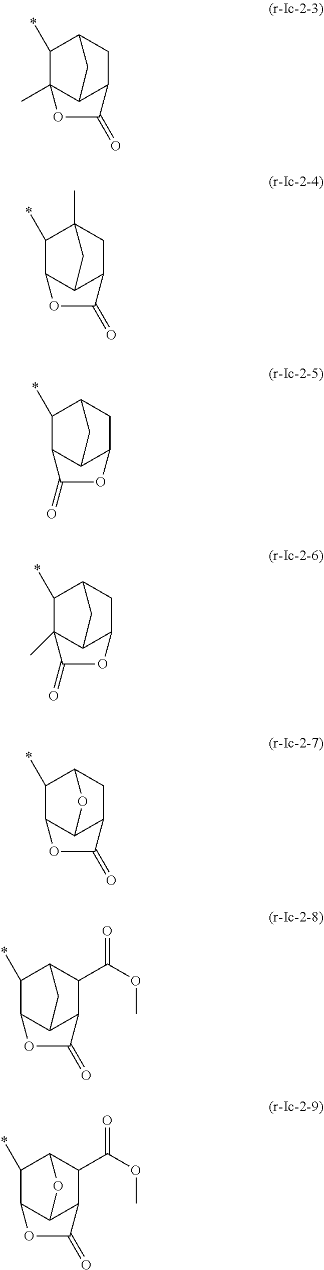

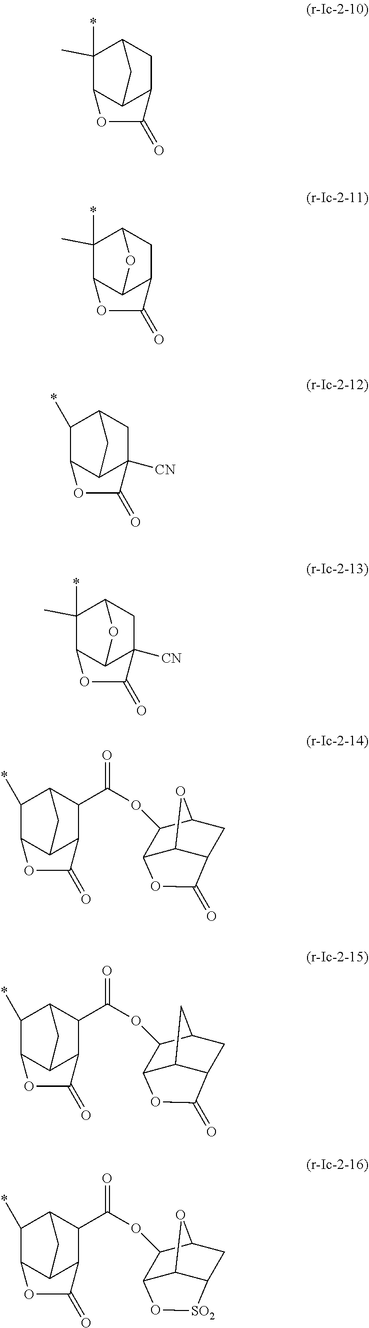

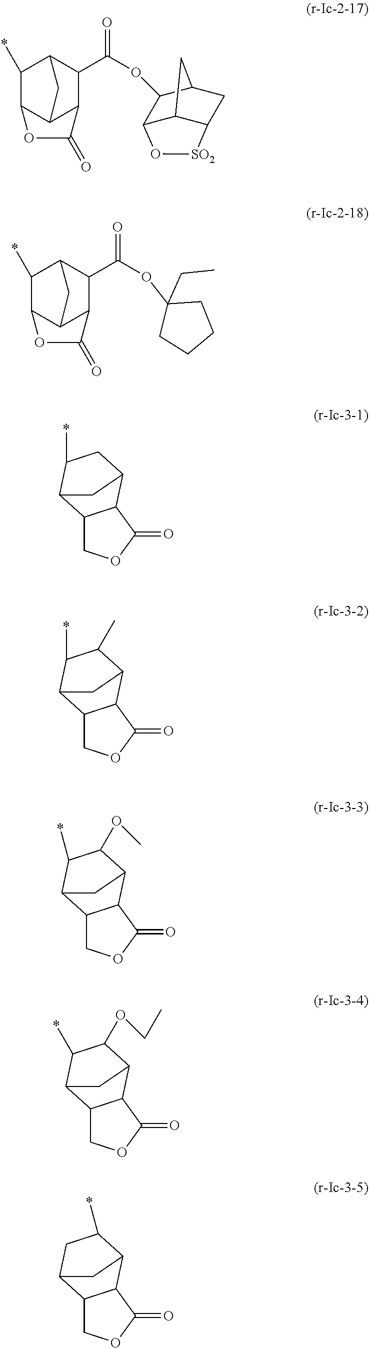

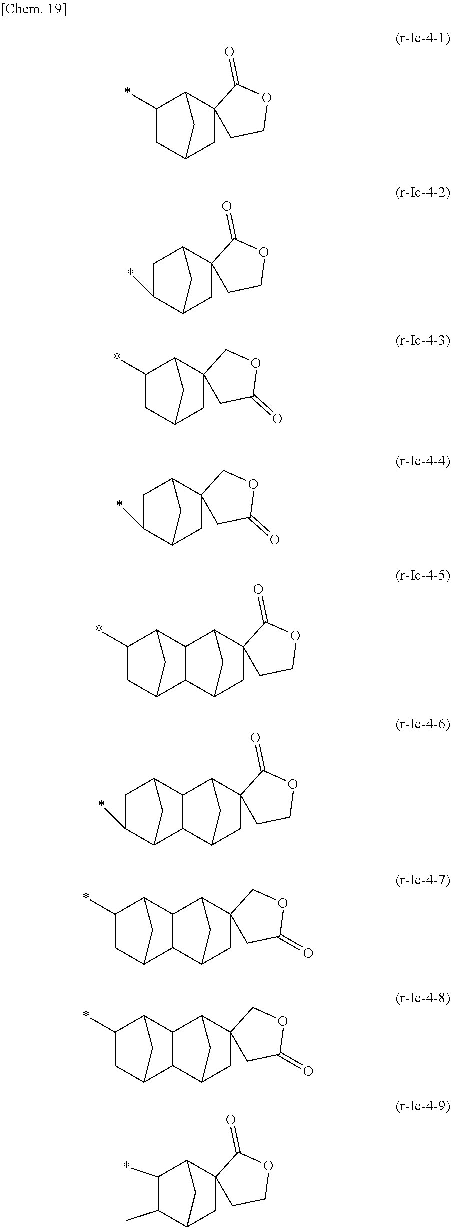

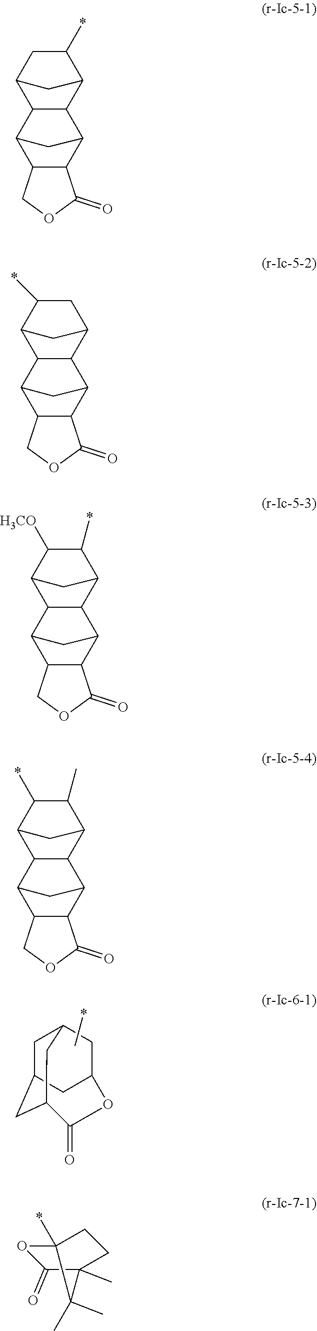

In General formulae (b5-r-1) to (b5-r-2) above, B″ is an alkylene group having 1 or more and 5 or less carbon atoms and optionally containing an oxygen atom or a sulfur atom, an oxygen atom, or sulfur atom. B″ is preferably an alkylene group having 1 or more and 5 or less carbon atoms or —O—, more preferably an alkylene group having 1 or more and 5 or less carbon atoms, and further preferably a methylene group.

In General formulae (b5-r-1) to (b5-r-4), Rb′⁵¹ are each independently a hydrogen atom, an alkyl group, an alkoxy group, a halogen atom, a halogenated alkyl group, a hydroxy group, —COOR″, —OC(═O)R″, a hydroxyalkyl group, or a cyano group, and among these, preferably each independently a hydrogen atom or a cyano group.

Specific examples of a group represented by each of General formulae (b5-r-1) to (b5-r-4) will be shown below. In General formula below, “Ac” denotes an acetyl group.

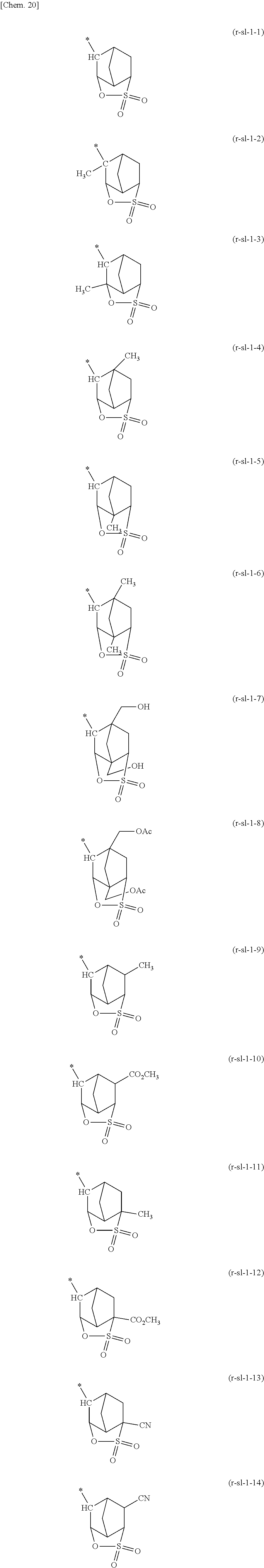

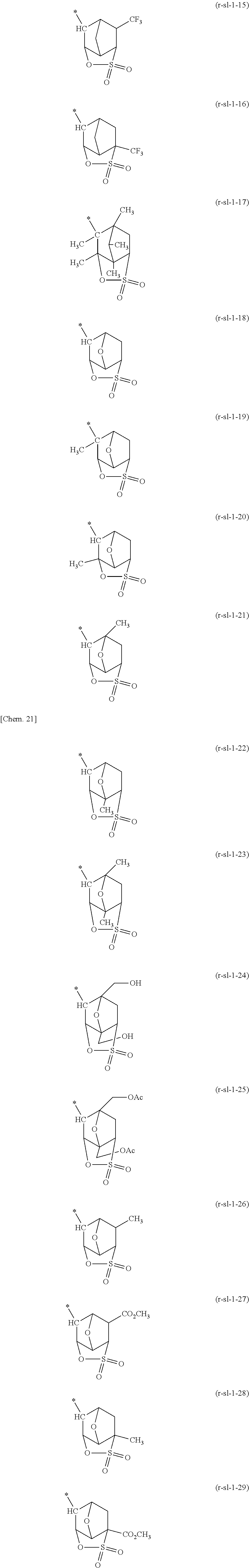

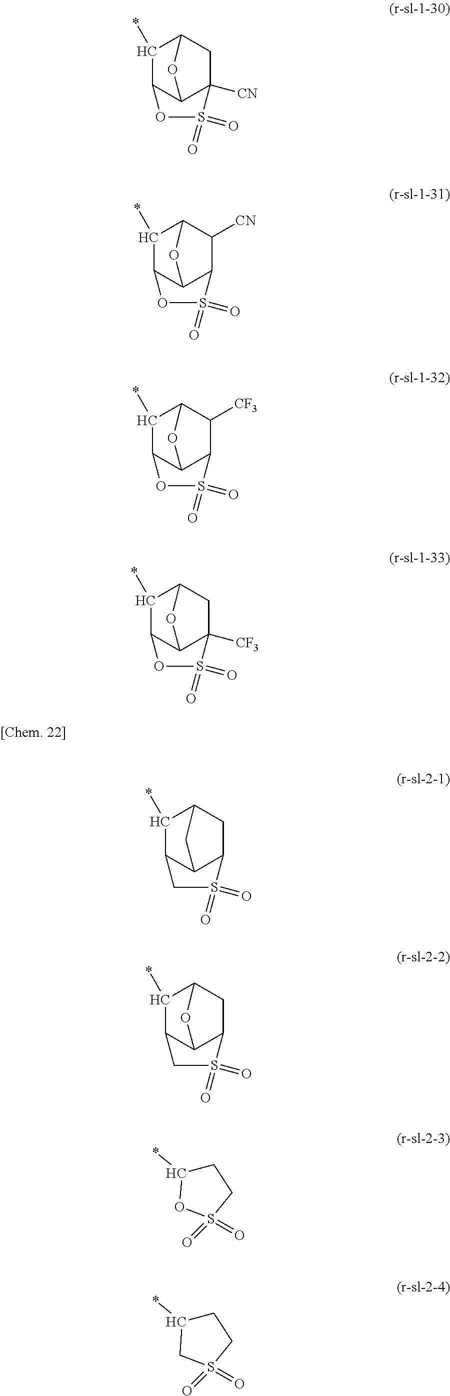

A cyclic group for Yb⁰ may have a substituent. Examples of the substituent include an alkyl group, an alkoxy group, a halogen atom, a halogenated alkyl group, a hydroxy group, a carbonyl group, a nitro group, etc. An alkyl group for the substituent is preferably an alkyl group having 1 or more and 5 or less carbon atoms. An alkoxy group for the substituent is preferably an alkoxy group having 1 or more and 5 or less carbon atoms, more preferably a methoxy group, an ethoxy group, an n-propoxy group, an iso-propyloxy group, an n-butoxy group, or a tert-butoxy group, and most preferably a methoxy group or an ethoxy group. A halogen atom for the substituent is preferably a fluorine atom, an iodine atom, or a bromine atom. Examples of a halogenated alkyl group for the substituent include a group in which a part or all of hydrogen atoms in an alkyl group having 1 or more and 5 or less carbon atoms such as a methyl group, an ethyl group, a propyl group, an n-butyl group, or a tert-butyl group is substituted with the halogen atom. A carbonyl group for the substituent is a group that is substituted for a methylene group (—CH₂—) constituting a cyclic hydrocarbon group.

A cyclic hydrocarbon group for Yb⁰ may be a fused ring group including a fused ring of an aliphatic hydrocarbon ring and an aromatic ring. Examples of the fused ring include a fused ring in which one or more aromatic rings are fused to a polycycloalkane having a polycyclic skeleton of a bridge ring system. Specific examples of the bridge ring system polycycloalkane include a bicycloalkane such as bicyclo[2.2.1]heptane (norbornane), bicyclo[2.2.2]octane, etc. The fused ring is preferably a group including a fused ring in which two or three aromatic rings are fused to a bicycloalkane and more preferably a group including a fused ring in which two or three aromatic rings are fused to bicyclo[2.2.2]octane. Specific examples of the fused ring group for Yb⁰ include groups represented by General formulae (r-br-1) to (r-br-2) below. In General formulae below, * represents an atomic bond to L⁰ in Formula (b0); and Rx⁰ represents a substituent.

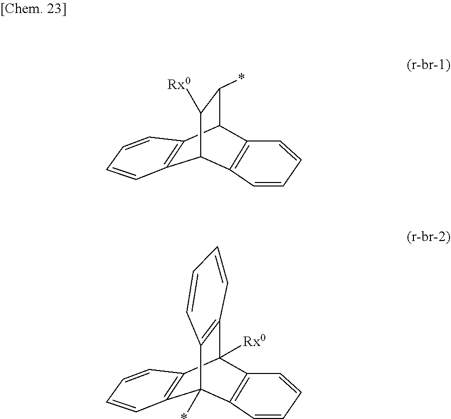

A substituent that the fused ring group for Yb⁰ may have includes an alkyl group, an alkoxy group, a halogen atom, a halogenated alkyl group, a hydroxy group, a carbonyl group, a nitro group, an aromatic hydrocarbon group, an alicyclic hydrocarbon atom, etc. The alkyl group, the alkoxy group, the halogen atom, or the halogenated alkyl group for the substituent in the fused ring group may be the same as those exemplified as the substituent in the cyclic group. Examples of the aromatic hydrocarbon group for the substituent in the fused ring group include a group in which one hydrogen atom is removed from an aromatic ring (an aryl group: e.g., a phenyl group, a naphthyl group, etc.), a group in which one hydrogen atom in the aromatic ring is substituted with an alkylene group (e.g., an arylalkyl group such as a benzyl group, a phenethyl group, a 1-naphthylmethyl group, a 2-naphthylmethyl group, a 1-naphthylethyl group, a 2-naphthylethyl group, etc.), a heterocyclic group represented by each of Formulae (r-hr-1) to (r-hr-6) above, etc. Examples of the alicyclic hydrocarbon group for the substituent in the fused ring group include a group in which one hydrogen atom is removed from a monocycloalkane such as cyclopentane or cyclohexane; a group in which one hydrogen atom is removed from a polycycloalkane such as adamantane, norbornane, isobornane, tricyclododecane, or tetracyclododecane; a lactone-containing cyclic group represented by each of General formulae (a2-r-1) to (a2-r-7) above; a —SO₂— containing cyclic group represented by each of General formulae (b5-r-1) to (b5-r-4) above; a heterocyclic group represented by each of Formulae (r-hr-7) to (r-hr-16) above, etc.

The substituent in the fused ring group may be an alkyl group partially substituted with a heteroatom-containing group. The alkyl group as the substituent in the fused ring group may be an alkyl group in which a part of hydrogen atoms may be substituted with a heteroatom-containing group. Alternatively, the alkyl group as the substituent in the fused ring group may be an alkyl group in which a part of carbon atoms constituting a hydrocarbon chain (e.g., a methylene group) may be substituted with a heteroatom-containing group. Examples of the heteroatom include an oxygen atom, a sulfur atom, a nitrogen atom, etc.

The heteroatom-containing group which is substituted for a hydrogen atom in the alkyl group may be a hydroxy group, an alkoxy group, a halogen atom, a halogenated alkyl group, a carboxy group, etc.

The heteroatom-containing group which is substituted for a carbon atom constituting a hydrocarbon chain in the alkyl group may be —O—, —C(═O)—O—, —O—C(═O)—, —C(═O)—, —O—C(═O)—O—, —C(═O)—NH—, —NH—, —S—, —S(═O)₂—, —S(═O)₂—O—, etc. The heteroatom-containing group is preferably —O—, —C(═O)—O—, —O—C(═O)—, or —S(═O)₂—O— and more preferably —C(═O)—O—.

A substituent in the fused ring group may be a group represented by —C(═O)—O—Rx⁰¹. Rx⁰¹ represents an alkyl group and may be linear, branched, or cyclic. A linear alkyl group may have 1 or more and 5 or less carbon atoms and more preferably is a methyl group, an ethyl group, an n-propyl group, or an n-butyl group. A branched alkyl group may have 3 or more and 5 or less carbon atoms, and is preferably an isopropyl group, a tert-butyl group, a sec-butyl group, or an isobutyl group. A cyclic alkyl group may be a group in which one hydrogen atom is removed from a cycloalkane having 1 or more and 8 or less carbon atoms, and is preferably a cyclopropyl group, a cyclobutyl group, a cyclopentyl group, or a cyclohexyl group and more preferably a cyclopentyl group or a cyclohexyl group.

Yb⁰ is preferably an adamantyl group which may have a substituent; a cyclic group having a steroid skeleton that may have a substituent; a lactone-containing cyclic group represented by each of Formula (a2-r-1) to (a2-r-7) above; a —SO₂— containing cyclic group represented by each of Formulae (b5-r-1) to (b5-r-4) above; a fused ring group containing a fused ring of an aliphatic hydrocarbon group and an aromatic ring; an aromatic hydrocarbon group that may have a substituent, etc. The fused ring group is preferably a group represented by Formula (r-br-1) or (r-br-2) above. A substituent in the adamantyl group may be a hydroxy group or a carbonyl group.

When L⁰-Yb⁰ is not —O—C(═O)—Yb⁰, L⁰ may be a divalent linking group including —C(═O)—O—; a divalent linking group including —S(═O)₂—O—; or a group represented by Formula (L01-3) except the case where nb03 is 1 and Lb⁰³¹ and Lb⁰³² are both single bonds. The divalent linking group including —C(═O)—O— may be a group represented by Formula (L01-1) above and preferably a group represented by Formula (L0-1-1), (L0-1-2), or (L0-1-5) above. The divalent linking group including —S(═O)₂—O— may be a group represented by Formula (L01-2) above and preferably a group represented by Formula (L0-1-4) or (L0-1-5).

The case where L⁰-Yb⁰ is —O—C(═O)—Yb⁰:
in this case, Yb⁰ is an alicyclic group that may have a substituent, a fused ring group that may have a substituent of an aliphatic ring and an aromatic ring, or an aromatic hydrocarbon group that has a substituent. The aromatic hydrocarbon group has at least one hydrogen atom on an aromatic ring substituted with an alkyl group or an alkoxy group.

An alicyclic group that may have a substituent for Yb⁰ may be the same as those described in “the case where L⁰-Yb⁰ is not —O—C(═O)—Yb⁰”. Examples of the alicyclic group include a group in which one hydrogen atom is removed from a monocycloalkane or a polycycloalkane; a cyclic group having a steroid skeleton; a lactone-containing cyclic group represented by each of Formulae (a2-r-1) to (a2-r-7) above; a —SO₂— containing cyclic group represented by each of Formulae (b5-r-1) to (b5-r-4) above; a heterocyclic group represented by each of Chemical formulae (r-hr-1) to (r-hr-16) above, etc. A substituent that the alicyclic group for Yb⁰ has may be the same as those described in “the case where L⁰-Yb⁰ is not —O—C(═O)—Yb”.

A fused ring group of an aliphatic ring and an aromatic ring for Yb⁰ may be the same as those described in “the case where L⁰-Yb⁰ is not —O—C(═O)—Yb⁰”. The fused ring group may be a group represented by Formula (r-br-1) or (r-br-2) above. A substituent that the fused ring group for Yb⁰ has may be the same as those described in “the case where L⁰-Yb⁰ is not —O—C(═O)—Yb⁰”.

An aromatic hydrocarbon group that has a substituent for Yb⁰ may be the same as those described in “the case where L⁰-Yb⁰ is not —O—C(═O)—Yb⁰”. However, the aromatic hydrocarbon group has at least one hydrogen atom on an aromatic ring substituted with an alkyl group or an alkoxy group. The aromatic ring may have an alkyl group, an alkoxy group, or both alkyl and alkoxy groups. The aromatic ring preferably has an alkoxy group.

The aromatic ring may have a substituent other than an alkyl group or an alkoxy group. Examples of the substituent include a halogen atom, a halogenated alkyl group, a hydroxy group, a carbonyl group, a nitro group, etc. Among these, the aromatic ring preferably has a halogen atom as a substituent and more preferably an iodine atom as a substituent.

An aromatic ring that the aromatic hydrocarbon group for Yb⁰ has is preferably a benzene ring or a naphthalene ring and more preferably a benzene ring.

When L⁰-Yb⁰ is —O—C(═O)—Yb⁰, Formula (b0) may be represented by Formula (b02-1) below:

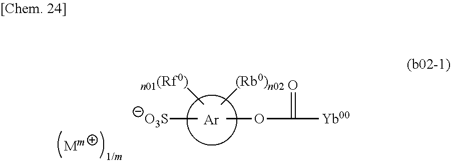

in which Ar, Rf⁰, Rb⁰, n01, and n02 are the same as Ar, Rf⁰, Rb⁰, n01, and n02 in Formula (b0) above, respectively; Yb⁰⁰ is an alicyclic group that may have a substituent, a fused ring group that may have a substituent of an aliphatic ring and an aromatic ring, or an aromatic hydrocarbon group that has a substituent and the aromatic hydrocarbon group has at least one hydrogen atom on an aromatic ring substituted with an alkyl group or an alkoxy group; m is an integer of 1 or more; and M^{m+} represents an m-valent cation.

A (B0) component is preferably a compound represented by General formula (b0-1) below:

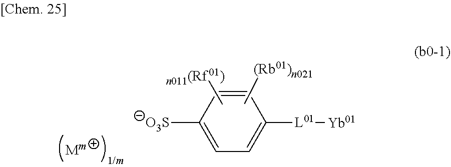

in which Rf⁰¹ represents a fluorinated alkyl group having 1 or more and 5 or less carbon atoms or a fluorine atom; L⁰¹ represents a divalent linking group including —C(═O)—O—, —O—C(═O), — or —O—S(═O)₂—; Yb⁰¹ represents a cyclic group; Rb⁰¹ represents an organic group; n011 is an integer of 1 or more; n021 is an integer of 0 or more; n011+n021≤4, provided that, when L⁰¹-Yb⁰¹ is —O—C(═O)—Yb⁰¹, Yb⁰¹ is an alicyclic group that may have a substituent, a fused ring group that may have a substituent of an aliphatic ring and an aromatic ring, or an aromatic hydrocarbon group that has a substituent and the aromatic hydrocarbon group has at least one hydrogen atom on an aromatic ring substituted with an alkyl group or an alkoxy group; when n011 is 2 or more, a plurality of Rf⁰¹ may be the same as or different from each other; when n021 is 2 or more, a plurality of Rf⁰¹ may be the same as or different from each other; m is an integer of 1 or more; and M^{m+} represents an m-valent cation.

In Formula (b0-1) above, Rf⁰¹, Rb⁰¹, L⁰¹, and Yb⁰¹ are the same as Rf⁰, Rb⁰, L⁰, and Yb⁰ in Formula (b0) above, respectively. n011 is preferably an integer of 1 or more and 4 or less, more preferably an integer of 2 or more and 4 or less, further preferably 3 or 4, and particularly preferably 4. n021 is preferably an integer of 0 or more and 3 or less, more preferably an integer of 0 or more and 2 or less, further preferably 0 or 1, and particularly preferably 0.

A (B0) component is more preferably a compound represented by General formula (b0-1-1) below:

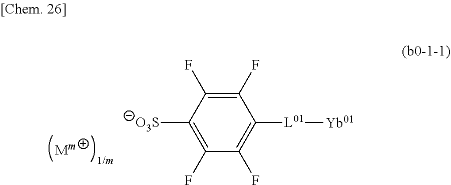

in which L⁰¹ and Yb⁰¹ may be the same as L⁰¹ and Yb⁰¹ in Formula (bc-1) above, respectively; m is an integer of 1 or more; and M^{m+} represents an m-valent organic cation.

Specific examples of the (B0) component are shown below, but are not limited thereto. In Formulae below, m is an integer of 1 or more and M^{m+} represents an m-valent cation.

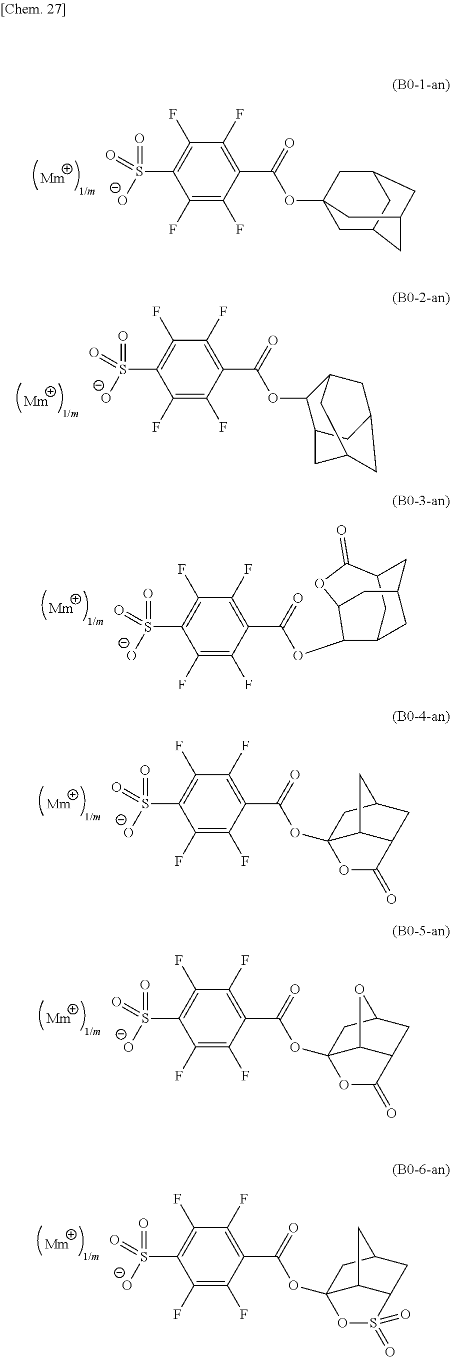

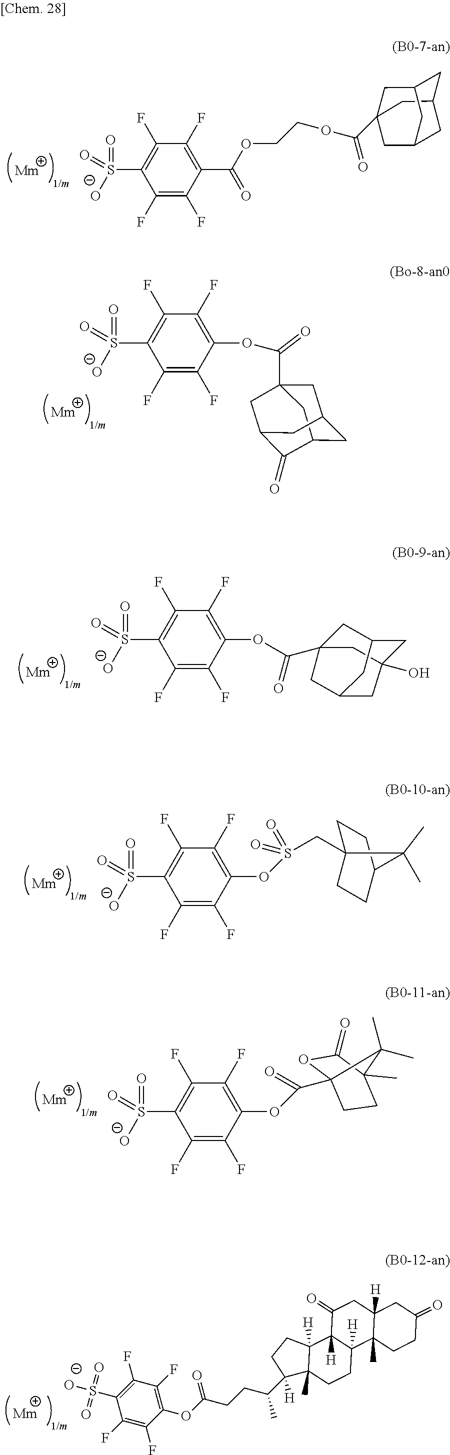

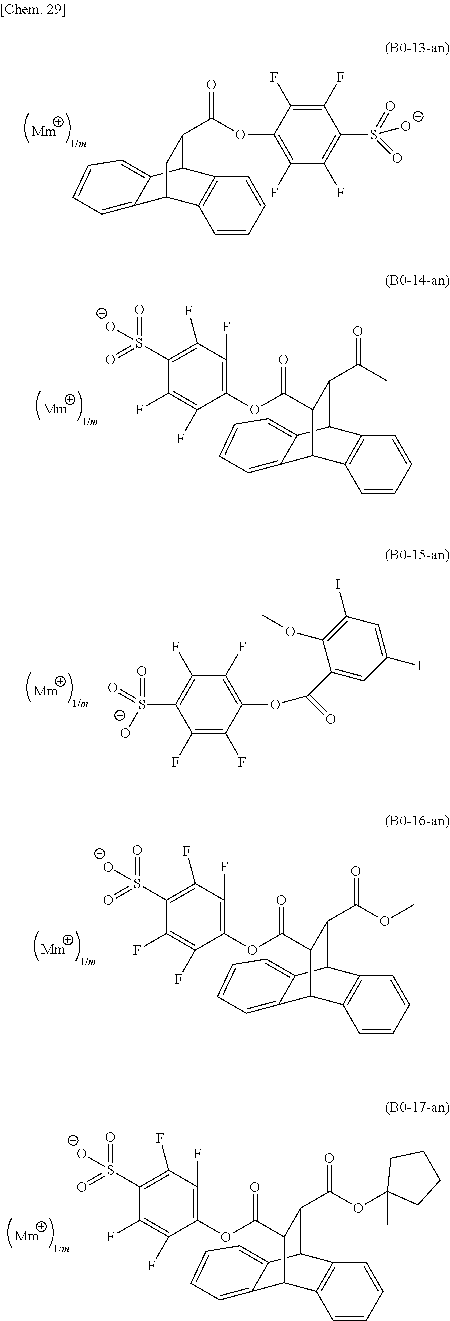

### (Cationic Moiety)

In Formula (b-0) above, M^{m+} represents an m-valent onium cation. The onium cation is preferably a sulfonium cation or an iodonium cation. m is an integer from 1 or more.

Preferred examples of a cationic moiety ((M^{m+})_{1/m}) include an organic cation represented by each of General formulae (ca-1) to (ca-3) below:

### [Chem. 30]

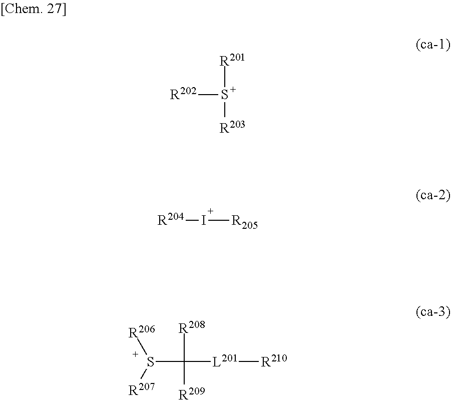

in which R²⁰¹ to R²⁰⁷ are each independently an aryl group, an alkyl group, or an alkenyl group, which may have a substituent; R²⁰¹ to R²⁰³ or R²⁰⁶ to R²⁰⁷ may be linked to each other to form a ring together with a sulfur atom in the formula; R²⁰⁸ to R²⁰⁹ are each independently a hydrogen atom or an alkyl group having 1 or more and 5 or less carbon atoms; R²¹⁰ is an aryl group that may have a substituent, an alkyl group that may have a substituent, an alkenyl group that may have a substituent, or a —SO₂— containing cyclic group that may have a substituent; and L2⁰¹ represents —C(═O)— or —C(═O)—O—.

In General formulae (ca-1) and (ca-3) above, an aryl group for R²⁰¹ to R²⁰⁷ may be an unsubstituted aryl group having 6 or more and 20 or more carbon atoms and preferably a phenyl group or a naphthyl group. An alkyl group for R²⁰¹ to R²⁰⁷ is preferably a chain or cyclic alkyl group having 1 or more and 30 or less carbon atoms. An alkenyl group for R²⁰¹ to R²⁰⁸⁷ preferably has 2 or more and 10 or less carbon atoms. Examples of a substituent that R²⁰¹ to R²⁰⁷ and R²¹⁰ may have include an alkyl group, a halogen atom, a halogenated alkyl group, a carbonyl group, a cyano group, an amino group, an aryl group, or a group represented by each of General formulae (ca-r-1) to (ca-r-7) below:

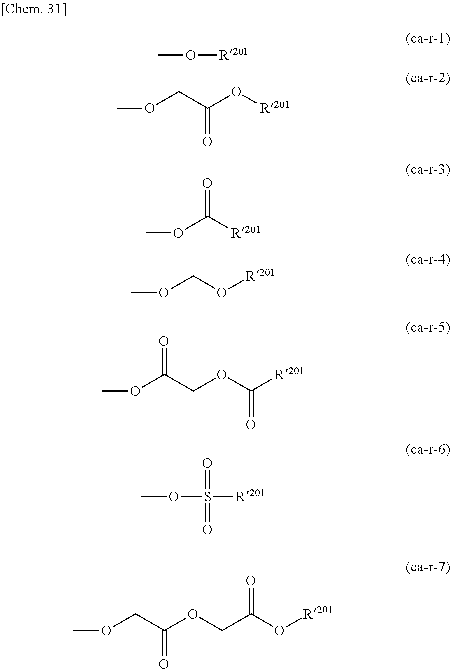

in which R′²⁰¹ are each independently a hydrogen atom, a cyclic group that may have a substituent, a chain alkyl group that may have a substituent, or a chain alkenyl group that may have a substituent.
   Cyclic Group that May have a Substituent:

The cyclic group is preferably a cyclic hydrocarbon group and the cyclic hydrocarbon group may be an aromatic hydrocarbon group or an aliphatic hydrocarbon group. The aliphatic hydrocarbon group means a hydrocarbon group that is not aromatic. Furthermore, the aliphatic hydrocarbon group may be saturated or unsaturated, and is usually preferably saturated.

An aromatic hydrocarbon group for R′²⁰¹ is a hydrocarbon group having an aromatic ring. A number of carbon atoms in the aromatic hydrocarbon group is preferably 3 or more and 30 or less, more preferably 5 or more and 30 or less, further preferably 5 or more and 20 or less, particularly preferably 6 or more and 15 or less, and most preferably 6 or more and 10 or less. However, the number of carbon atoms shall not include a number of carbon atoms in a substituent. Specific examples of an aromatic ring that the aromatic hydrocarbon group for R′²⁰¹ has include benzene, fluorene, naphthalene, anthracene, phenanthrene, biphenyl, or an aromatic heterocyclic ring in which a part of carbon atoms constituting the above-mentioned aromatic hydrocarbon ring is substituted with a heteroatom; etc. Examples of a heteroatom in the aromatic heterocyclic ring include an oxygen atom, a sulfur atom, a nitrogen atom, etc. Specific examples of the aromatic hydrocarbon group for R′²⁰¹ include a group in which one hydrogen atom is removed from the aromatic ring (an aryl group: e.g., a phenyl group, a naphthyl group, etc.), a group in which one hydrogen atom in the aromatic ring is substituted with an alkylene group (e.g., an arylalkyl group such as a benzyl group, a phenethyl group, a 1-naphthylmethyl group, a 2-naphthylmethyl group, a 1-naphthylethyl group, a 2-naphthylethyl group, etc.), etc. The alkylene group (an alkyl chain in the arylalkyl group) has preferably 1 or more and 4 or less carbon atoms, more preferably 1 or 2 carbon atoms, and particularly preferably 1 carbon atom.

A cyclic aliphatic hydrocarbon group for R′²⁰¹ may be an aliphatic hydrocarbon group including a ring in its structure. Examples of the aliphatic hydrocarbon group including a ring in its structure include an alicyclic hydrocarbon group (a group in which one hydrogen atom is removed from an aliphatic hydrocarbon ring), a group in which an alicyclic hydrocarbon group is attached to an end of a linear- or branched-aliphatic hydrocarbon group, a group in which a linear- or branched-aliphatic hydrocarbon group is interrupted by an alicyclic hydrocarbon group, etc. The alicyclic hydrocarbon group has preferably 3 or more and 20 or less carbon atoms and more preferably 3 or more and 12 or less carbon atoms. The alicyclic hydrocarbon group may be a polycyclic group or a monocyclic group. A monocyclic alicyclic hydrocarbon group is preferably a group in which one or more hydrogen atoms are removed from a monocycloalkane. The monocycloalkane preferably has 3 or more and 6 or less carbon atoms and specific examples thereof include cyclopentane, cyclohexane, etc. A polycyclic alicyclic hydrocarbon group is preferably a group in which one or more hydrogen atoms are removed from a polycycloalkane, and the polycycloalkane preferably has 7 or more and 30 or less carbon atoms. Among these, the polycycloalkane is more preferably a polycycloalkane having a polycyclic skeleton of a bridge ring system such as adamantane, norbornane, isobornane, tricyclodecane, or tetracyclododecane; a polycycloalkane having a polycyclic skeleton of a fused ring system such as a cyclic group having a steroid skeleton.

Among these, the cyclic aliphatic hydrocarbon group for R′²⁰¹ is preferably a group in which one or more hydrogen atoms are removed from a monocycloalkane or a polycycloalkane, more preferably a group in which one hydrogen atom is removed from a polycycloalkane, particularly preferably an adamantyl group or a norbornyl group, and most preferably an adamantyl group.

A linear or branched aliphatic hydrocarbon group that may be attached to an alicyclic hydrocarbon group preferably has 1 or more and 10 or less carbon atoms, more preferably 1 or more and 6 or less carbon atoms, further preferably 1 or more and 4 or less carbon atoms, and particularly preferably 1 or more and 3 or less carbon atoms. A linear aliphatic hydrocarbon group is preferably a linear alkylene group, specifically, a methylene group [—CH₂—], an ethylene group [—(CH₂)₂—], a trimethylene group [—(CH₂)₃—], a tetramethylene group [—(CH₂)₄—], a pentamethylene group [—(CH₂)₅—], etc. A branched aliphatic hydrocarbon group is preferably a branched alkylene group, specifically, an alkylalkylene group, for example, an alkylmethylene group such as —CH(CH₃)—, —CH(CH₂CH₃)—, —C(CH₃)₂—, —C(CH₃) (CH₂CH₃)—, —C(CH₃) (CH₂CH₂CH₃)—, or —C(CH₂CH₃)₂—; an alkylethylene group such as —CH(CH₃)CH₂—, —CH(CH₃)CH(CH₃)—, —C(CH₃)₂CH₂—, —CH(CH₂CH₃) CH₂—, or —C(CH₂CH₃)₂—CH₂—; an alkyltrimethylene group such as —CH(CH₃)CH₂CH₂— or —CH₂CH(CH₃)CH₂—; or an alkyltetramethylene group such as —CH(CH₃) CH₂CH₂CH₂— or —CH₂CH(CH₃) CH₂CH₂—, etc. An alkyl group in the alkylalkylene group is preferably a linear alkyl group having 1 or more and 5 or less carbon atoms.

A cyclic hydrocarbon group for R′²⁰¹ may include a heteroatom like a heterocycle. Specific examples thereof include a lactone-containing cyclic group represented by each of General formula (a2-r-1) to (a2-r-7) above, a —SO₂-containing cyclic group represented by each of General formula (b5-r-1) to (b5-r-4) above, or a heterocyclic group represented by each of General formula (r-hr-1) to (r-hr-16) above.

Examples of a substituent in a cyclic group for R′²⁰¹ include an alkyl group, an alkoxy group, a halogen atom, a halogenated alkyl group, a hydroxy group, a carbonyl group, a nitro group, etc. An alkyl group for the substituent is preferably an alkyl group having 1 or more and 5 or less carbon atoms and more preferably a methyl group, an ethyl group, a propyl group, an n-butyl group, or a tert-butyl group. An alkoxy group for the substituent is preferably an alkoxy group having 1 or more and 5 or less carbon atoms, more preferably a methoxy group, an ethoxy group, an n-propoxy group, an iso-propoxy group, an n-butoxy group, or a tert-butoxy group, and most preferably a methoxy group or an ethoxy group. A halogen atom for the substituent is preferably a fluorine atom. A halogenated alkyl group for the substituent may be a group in which a part or all of hydrogen atoms in an alkyl group having 1 or more and 5 or less carbon atoms such as a methyl group, an ethyl group, a propyl group, an n-butyl group, or a tert-butyl group is substituted with a halogen atom. A carbonyl group for the substituent is a group that is substituted for a methylene group (—CH₂—) constituting a cyclic hydrocarbon group.

Chain Alkyl Group that May have a Substituent:
a chain alkyl group for R′²⁰¹ may be linear or branched. A linear alkyl group preferably has 1 or more and 20 or less carbon atoms, more preferably 1 or more and 15 or less carbon atoms, and most preferably 1 or more and 10 or less carbon atoms. A branched alkyl group preferably has 3 or more and 20 or less carbon atoms, more preferably 3 or more and 15 or less carbon atoms, and most preferably 3 or more and 10 or less carbon atoms. Specific examples thereof include a 1-methylethyl group, a 1-methylpropyl group, a 2-methylpropyl group, a 1-methylbutyl group, a 2-methylbutyl group, a 3-methylbutyl group, a 1-ethylbutyl group, a 2-ethylbutyl group, a 1-methylpentyl group, a 2-methylpentyl group, a 3-methylpentyl group, a 4-methylpentyl group, etc.
   Chain Alkenyl Group that May have a Substituent:
a chain alkenyl group for R′²⁰¹ may be linear or branched and preferably has 2 or more and 10 or less carbon atoms, more preferably 2 or more and 5 or less carbon atoms, further preferably 2 or more and 4 or less carbon atoms, and particularly preferably 3 carbon atoms. A linear alkenyl group may be, for example, a vinyl group, a propenyl group (allyl group), a butynyl group, etc. A branched alkenyl group may be, for example, a 1-methylvinyl group, a 2-methylvinyl group, a 1-methylpropenyl group, a 2-methylpropenyl group, etc. Among these, the chain alkenyl group is preferably a linear alkenyl group, more preferably a vinyl group or a propenyl group, and particularly preferably a vinyl group.

Examples of a substitute in the chain alkyl group or the chain alkenyl group for R′²⁰¹ include an alkoxy group, a halogen atom, a halogenated alkyl group, a hydroxy group, a carbonyl group, a nitro group, an amino group, the cyclic group for R′²⁰¹, etc.

A cyclic group that may have a substituent, a chain alkyl group that may have a substituent, or a chain alkenyl group that may have a substituent for R′²⁰¹ may be those described above, and, the cyclic group that may have a substituent or the chain alkyl group that may have a substituent may be the same as the acid-degradable group represented by Formula (a1-r-2) above.

Among these, R′²⁰¹ is preferably a cyclic group that may have a substituent and more preferably a cyclic hydrocarbon group that may have a substituent. More specifically, for example, a group in which one or more hydrogen atoms are removed from a phenyl group, a naphthyl group, or a polycycloalkane, a lactone-containing cyclic group represented by each of General formulae (a2-r-1) to (a2-r-7) above; or a —SO₂— containing cyclic group represented by each of General formulae (b5-r-1) to (b5-r-4) above is preferred.

In General formulae (ca-1) to (ca-3) above, when R²⁰¹ to R²⁰³ or R²⁰⁶ to R²⁰⁷ may be linked to each other to form a ring together with a sulfur atom in the formula, they may be attached via a functional group, for example, a heteroatom such as a sulfur atom, an oxygen atom, or a nitrogen atom, a carbonyl group, —SO—, —SO₂—, —SO₃—, —COO—, —CONH—, or —N(RN)— in which RN is an alkyl group having 1 or more and 5 or less carbon atoms. A ring in which one ring including the sulfur atom in the formula in its ring skeleton is preferably a 3 or more and 10 or less membered ring and particularly preferred a 5 or more and 7 or less membered ring including the sulfur atom is formed. Specific examples of the ring to be formed include a thiophene ring, a thiazole ring, a benzothiophene ring, a dibenzothiophene ring, a 9H-thioxanthene ring, a thioxanthone ring, a thianthrene ring, a phenoxathiin ring, a tetrahydrothiophenium ring, a tetrahydrothiopyranium ring, etc.

R²⁰⁸ to R²⁰⁹ each independently represent a hydrogen atom or an alkyl group having 1 or more and 5 or less carbon atoms, preferably a hydrogen atom or an alkyl group having 1 or more and 3 or less carbon atoms, in the case of the alkyl group, they may be attached to each other to form a ring.

R²¹⁰ is an aryl group that may have a substituent, an alkyl group that may have a substituent, an alkenyl group that may have a substituent, or a —SO₂— containing cyclic group that may have a substituent. An aryl group for R²¹⁰ may be an unsubstituted aryl group having 6 or more and 20 or more carbon atoms and preferably a phenyl group or a naphthyl group. An alkyl group for R²¹⁰ is preferably a chain or cyclic alkyl group having 1 or more and 30 or less carbon atoms. An alkenyl group for R²¹⁰ preferably has 2 or more and 10 or less carbon atoms. A —SO₂— containing cyclic group that may have a substituent for R²¹⁰ is preferably a “—SO₂-containing polycyclic group” and more preferably a group represented by General formula (b5-r-1).

Suitable specific examples of a cation represented by Formula (ca-1) above include a cation represented by each of Chemical formulae (ca-1-1) to (ca-1-75) below:

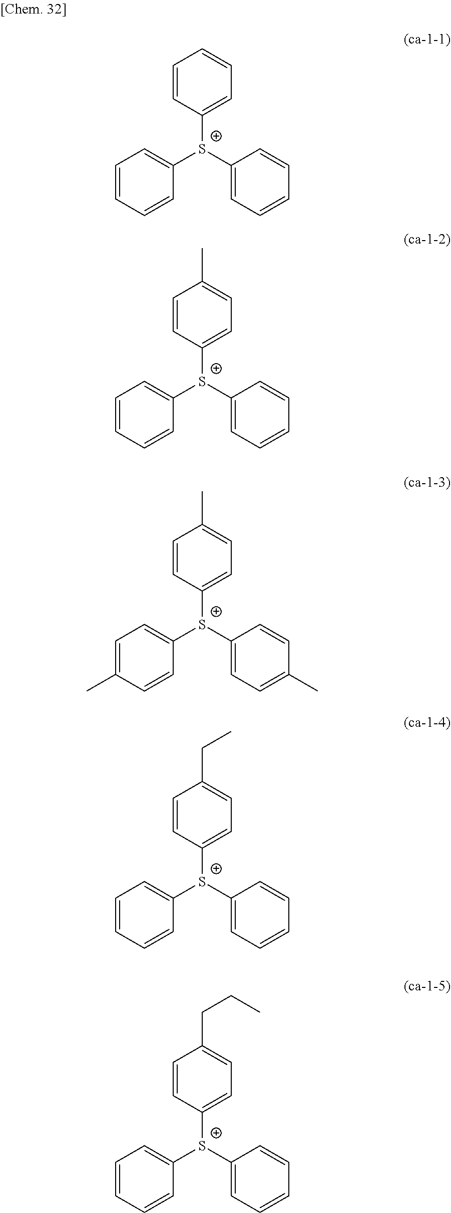

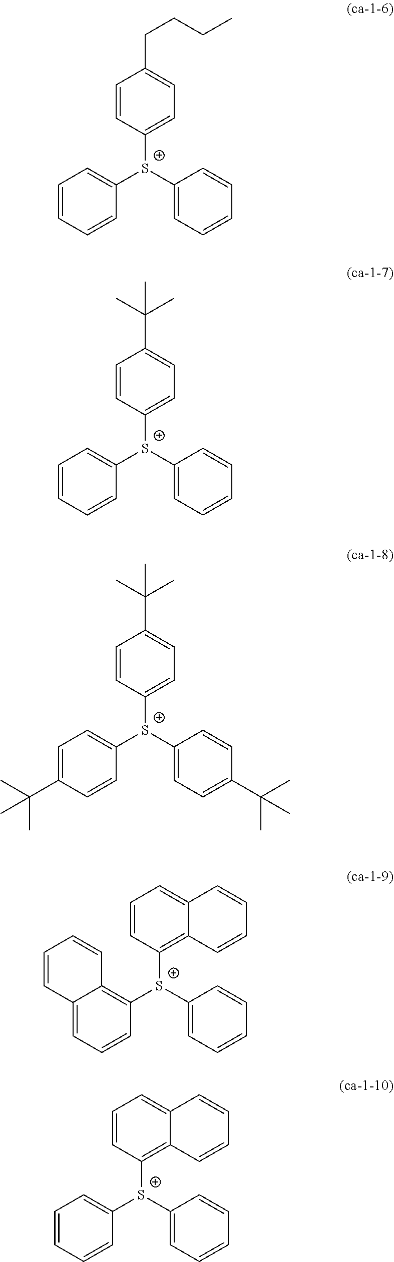

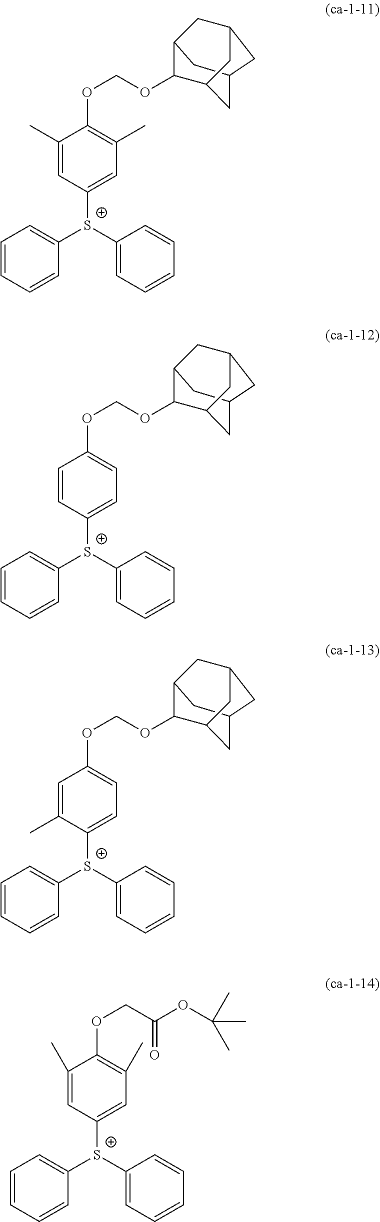

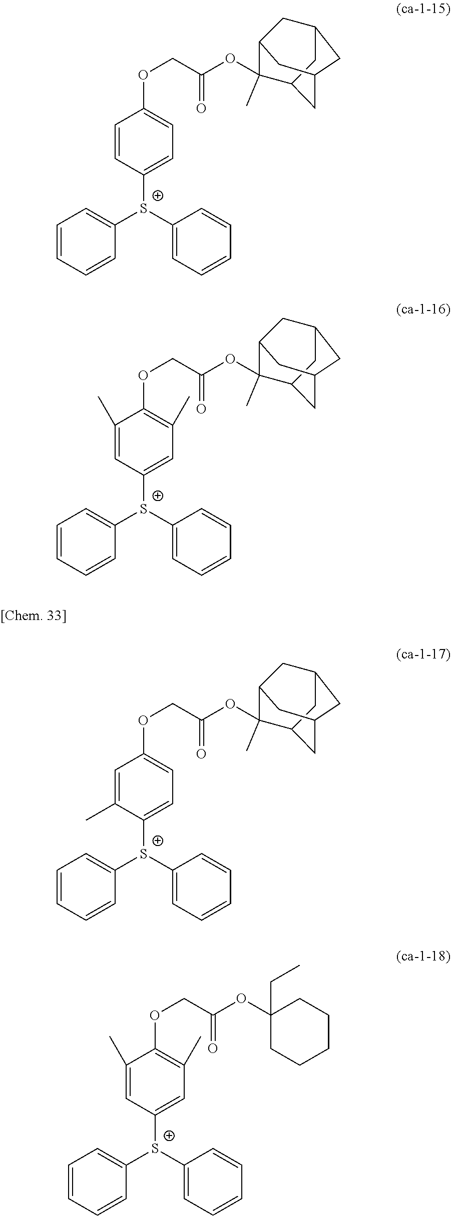

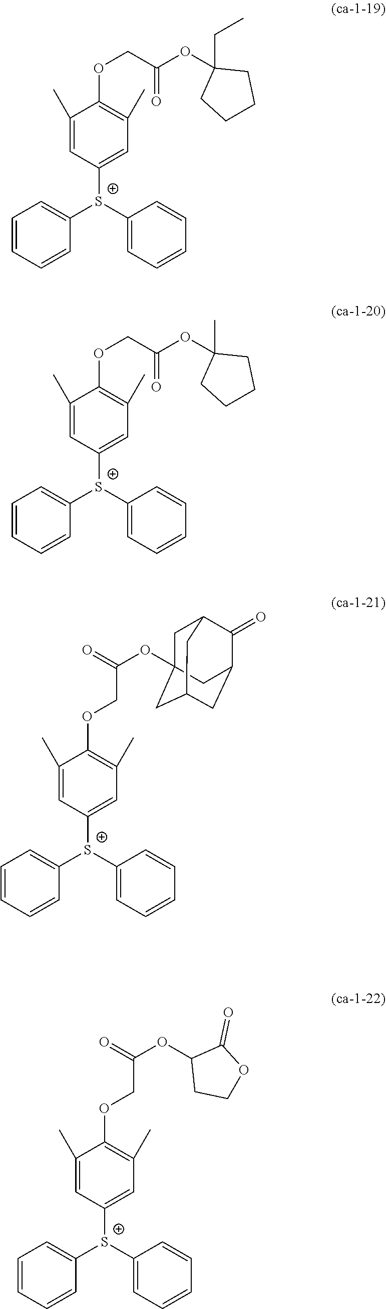

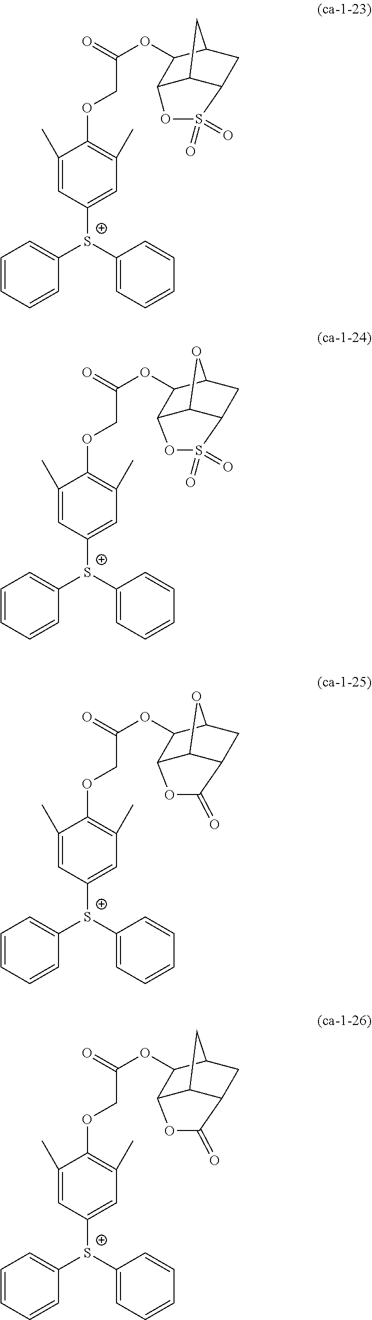

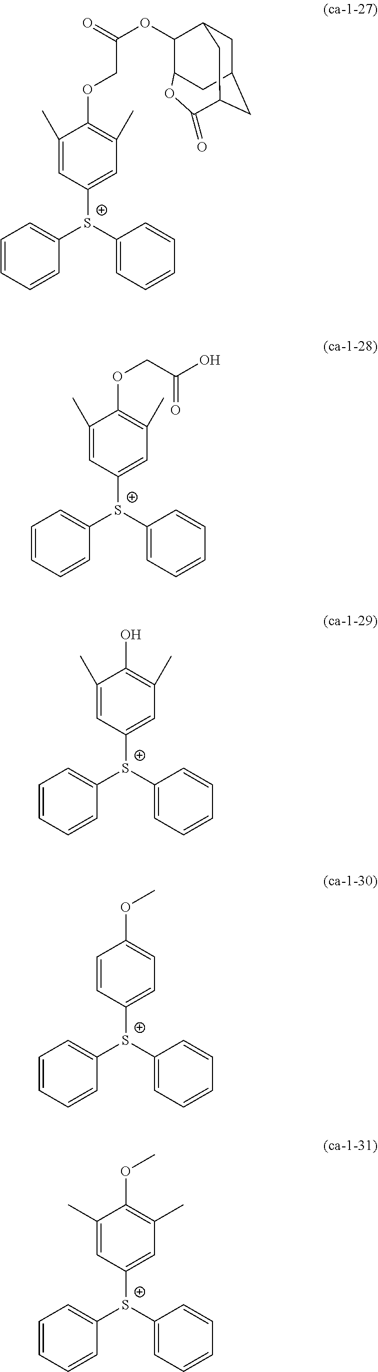

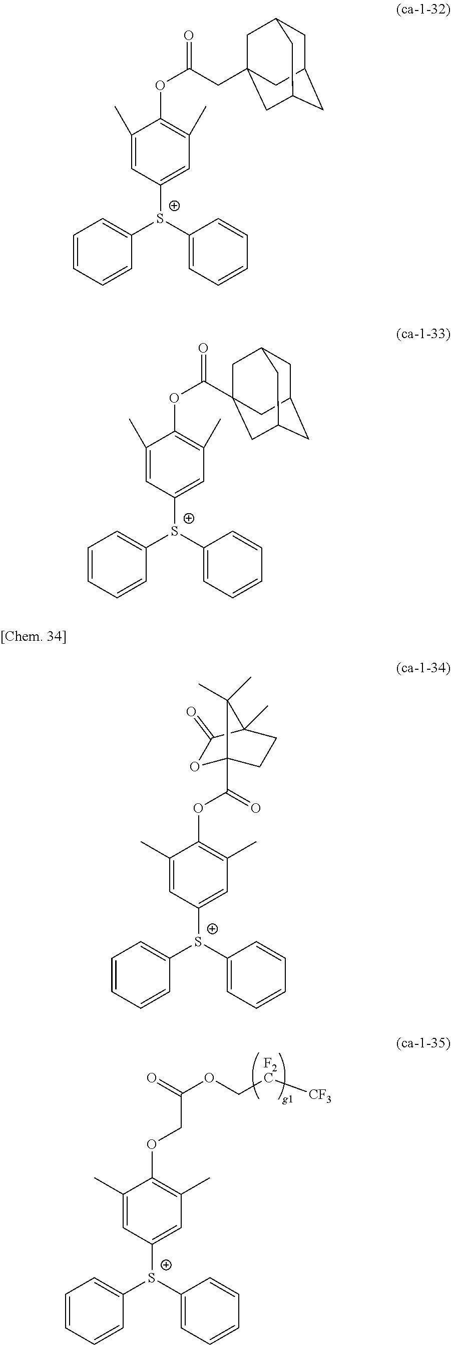

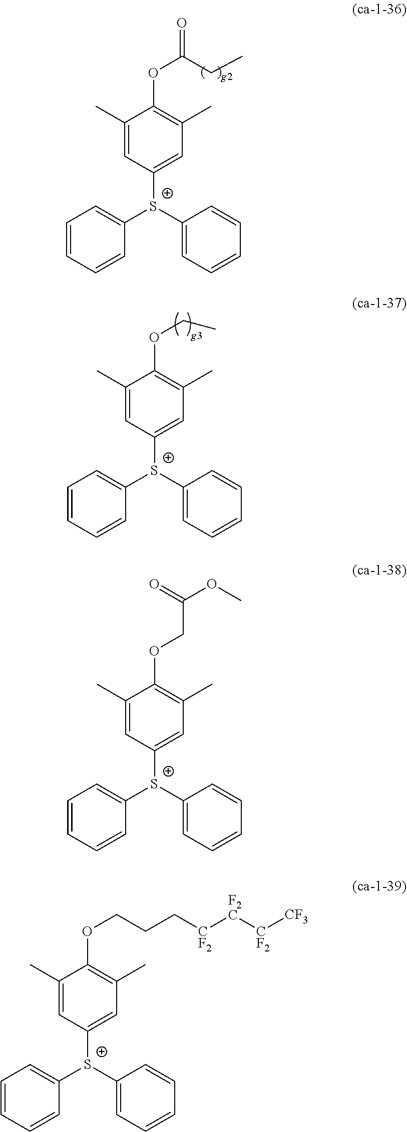

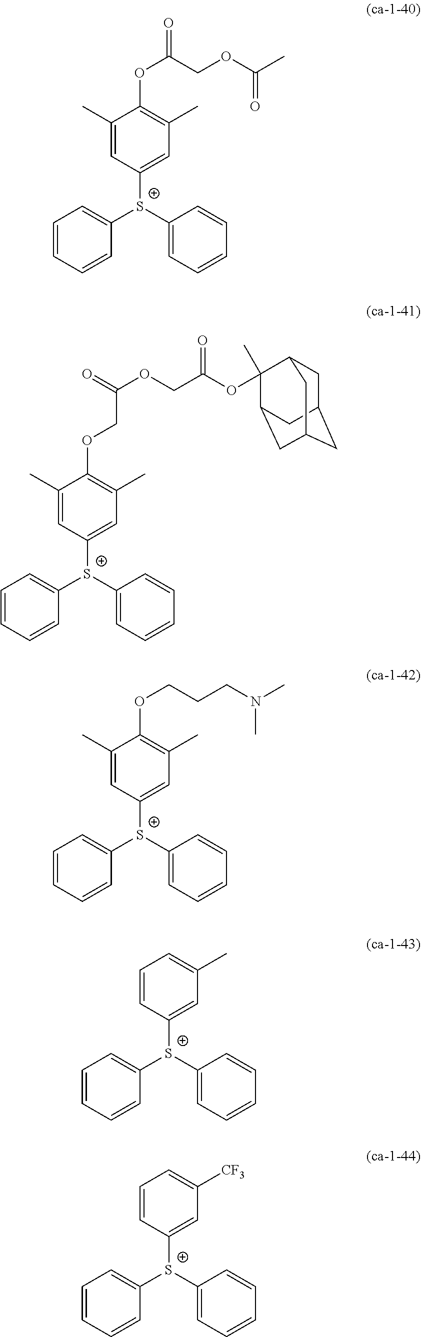

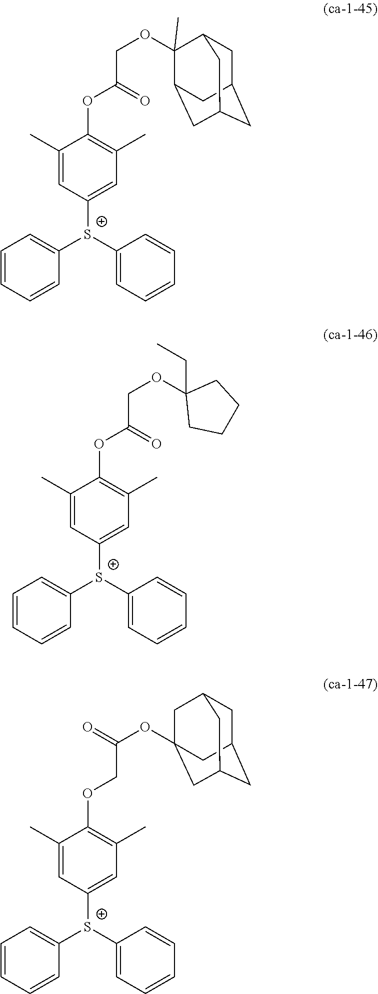

in which g1, g2, and g3 denotes a number of repetitions, g1 is an integer of 1 or more and 5 or less, g2 is an integer of 0 or more and 20 or less, and g3 is an integer of 0 or more and 20 or less.

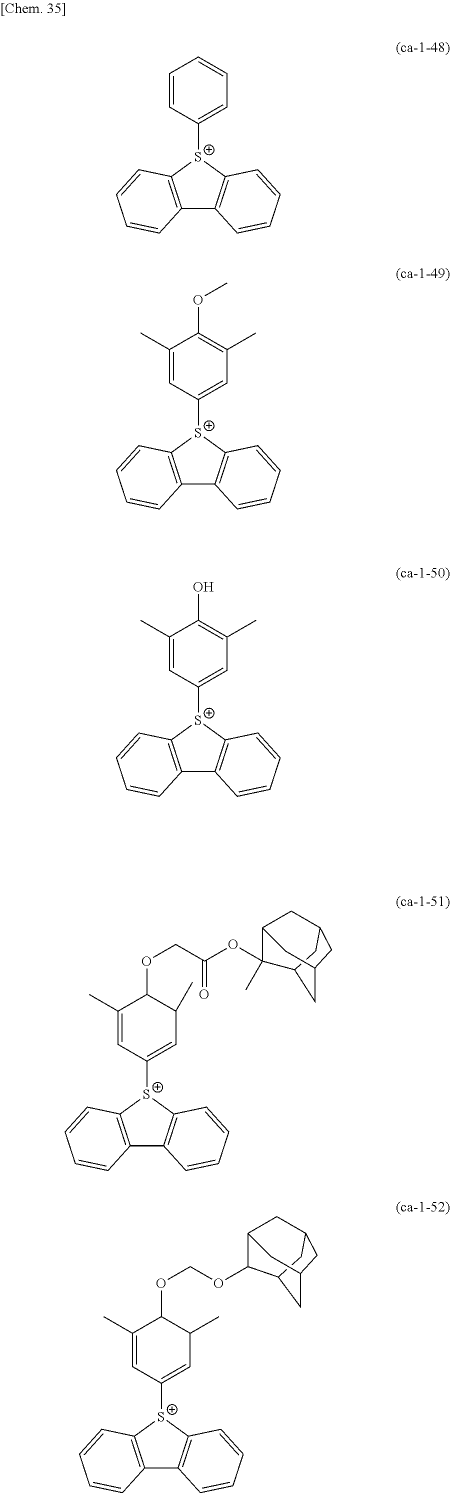 [SMILES: c1ccc(-[s+]2c3ccccc3c3ccccc32)cc1 ; COc1c(C)cc(-[s+]2c3ccccc3c3ccccc32)cc1C ; Cc1cc(-[s+]2c3ccccc3c3ccccc32)cc(C)c1O ; CC1=CC([s+]2c3ccccc3c3ccccc32)=CC(C)C1OCC(=O)OC1(C)C2CC3CC(C2)CC1C3 ; CC1=CC([s+]2c3ccccc3c3ccccc32)=CC(C)C1OCOC1C2CC3CC(C2)CC1C3]

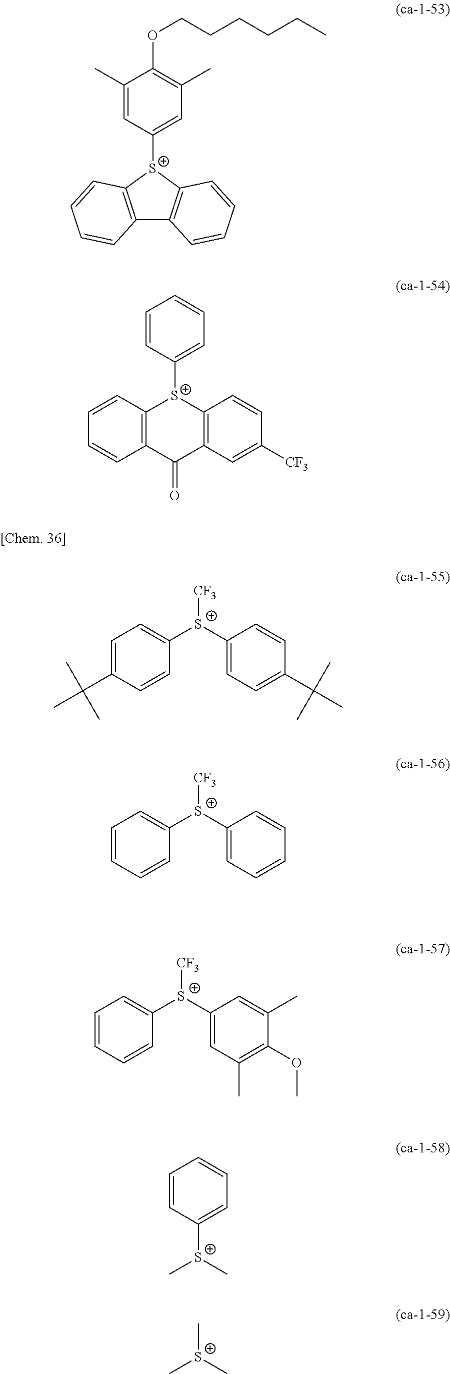

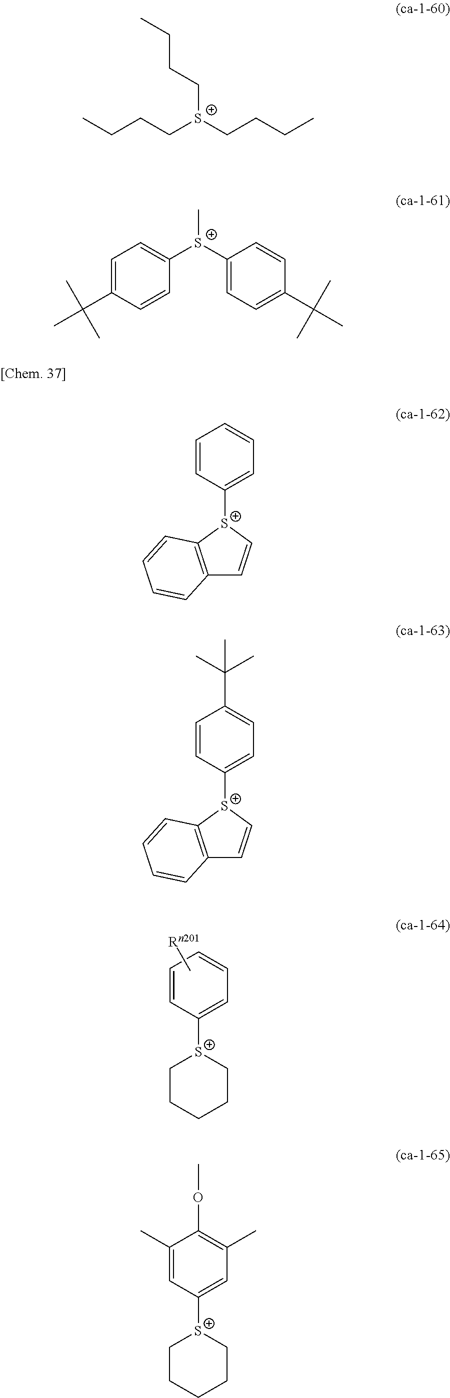

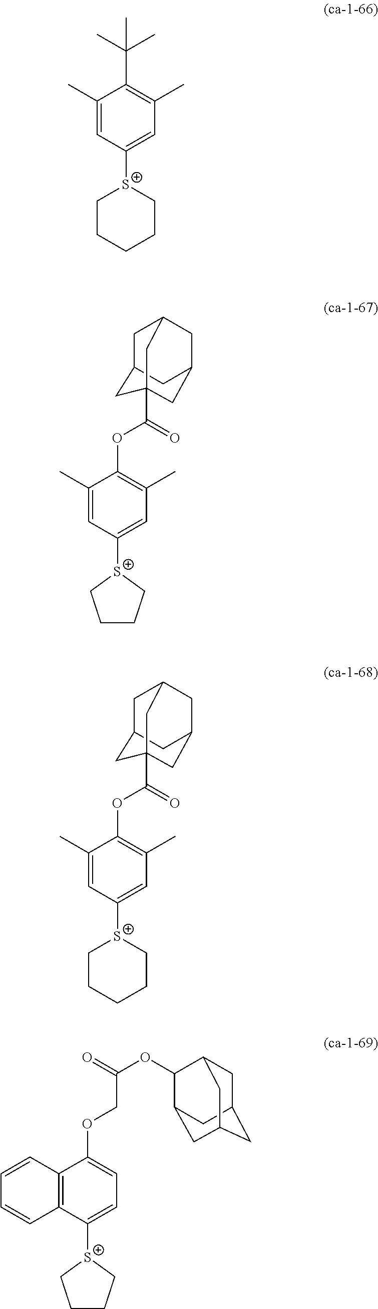

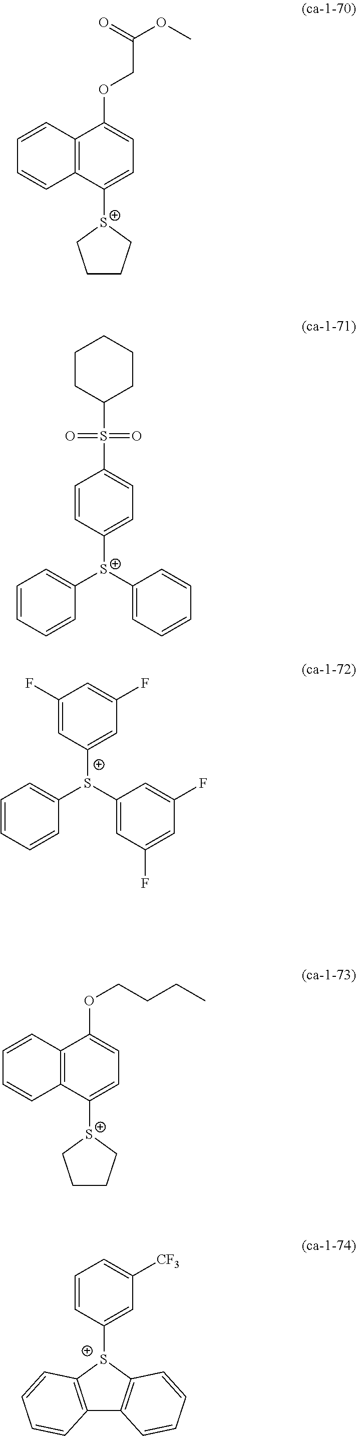 [SMILES: COC(=O)COc1ccc([S+]2CCCC2)c2ccccc12 ; O=S(=O)(c1ccc([S+](c2ccccc2)c2ccccc2)cc1)C1CCCCC1 ; Fc1cc(F)cc([S+](c2ccccc2)c2cc(F)cc(F)c2)c1 ; CCCCOc1ccc([S+]2CCCC2)c2ccccc12 ; FC(F)(F)c1cccc(-[s+]2c3ccccc3c3ccccc32)c1]

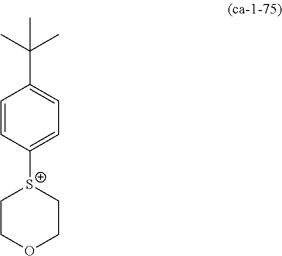 [SMILES: CC(C)(C)c1ccc([S+]2CCOCC2)cc1]

in which R″²⁰¹ is a hydrogen atom or a substituent and the substituent is the same as those exemplified as a substituent that R²⁰¹ to R²⁰⁷ or R²¹⁰ may have.

Suitable specific examples of a cation represented by Formula (ca-2) above include a diphenyliodonium cation or a bis(4-tert-butylphenyl)iodonium cation.

Suitable specific examples of a cation represented by Formula (ca-3) above include a cation represented by each of Formulae (ca-3-1) to (ca-3-6) below.

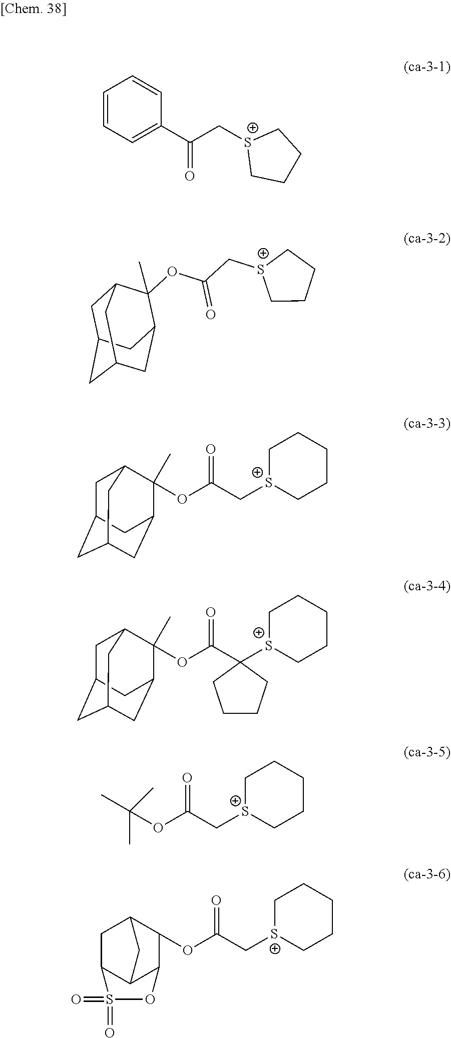 [SMILES: O=C(C[S+]1CCCC1)c1ccccc1 ; CC1(OC(=O)C[S+]2CCCC2)C2CC3CC(C2)CC1C3 ; CC1(OC(=O)C[S+]2CCCCC2)C2CC3CC(C2)CC1C3 ; CC1(OC(=O)C2([S+]3CCCCC3)CCCC2)C2CC3CC(C2)CC1C3 ; CC(C)(C)OC(=O)C[S+]1CCCCC1 ; O=C(C[S+]1CCCCC1)OC1C2CC3C1OS(=O)(=O)C3C2]

Among these, a cationic moiety ((M^{m+})_{1/n}) is preferably a cation represented by General formula (ca-1).

Specific examples of a (B0) component are shown below, but are not limited thereto.

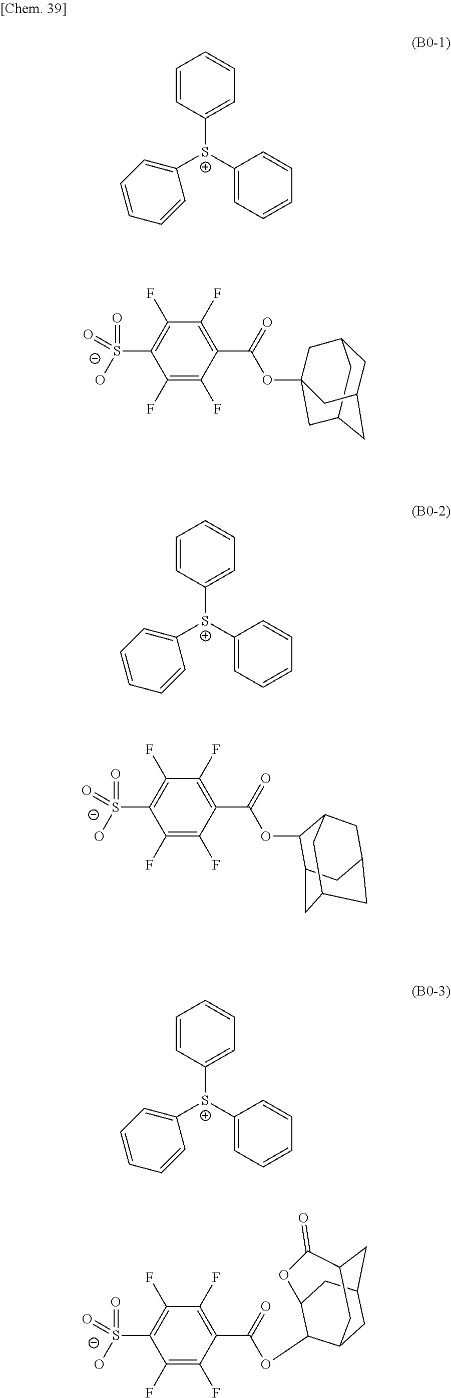 [SMILES: c1ccc([S+](c2ccccc2)c2ccccc2)cc1 ; O=C(OC12CC3CC(CC(C3)C1)C2)c1c(F)c(F)c(S(=O)(=O)[O-])c(F)c1F ; c1ccc([S+](c2ccccc2)c2ccccc2)cc1 ; O=C(OC1C2CC3CC(C2)CC1C3)c1c(F)c(F)c(S(=O)(=O)[O-])c(F)c1F ; c1ccc([S+](c2ccccc2)c2ccccc2)cc1 ; O=C(OC1C2CC3CC(C2)C(=O)OC1C3)c1c(F)c(F)c(S(=O)(=O)[O-])c(F)c1F]

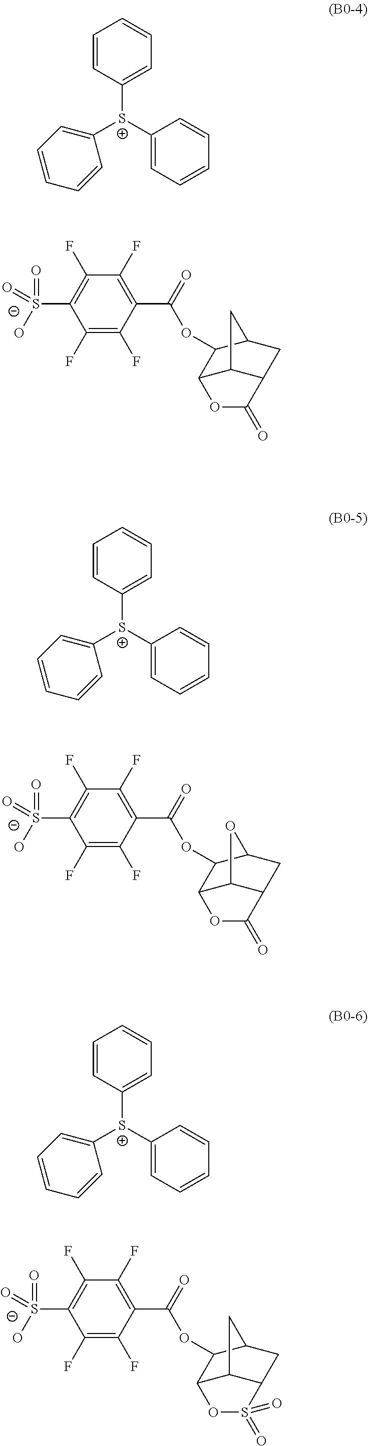 [SMILES: c1ccc([S+](c2ccccc2)c2ccccc2)cc1 ; O=C(OC1C2CC3C(=O)OC1C3C2)c1c(F)c(F)c(S(=O)(=O)[O-])c(F)c1F ; c1ccc([S+](c2ccccc2)c2ccccc2)cc1 ; O=C(OC1C2CC3C(=O)OC1C3O2)c1c(F)c(F)c(S(=O)(=O)[O-])c(F)c1F ; c1ccc([S+](c2ccccc2)c2ccccc2)cc1 ; O=C(OC1C2CC3C1OS(=O)(=O)C3C2)c1c(F)c(F)c(S(=O)(=O)[O-])c(F)c1F]

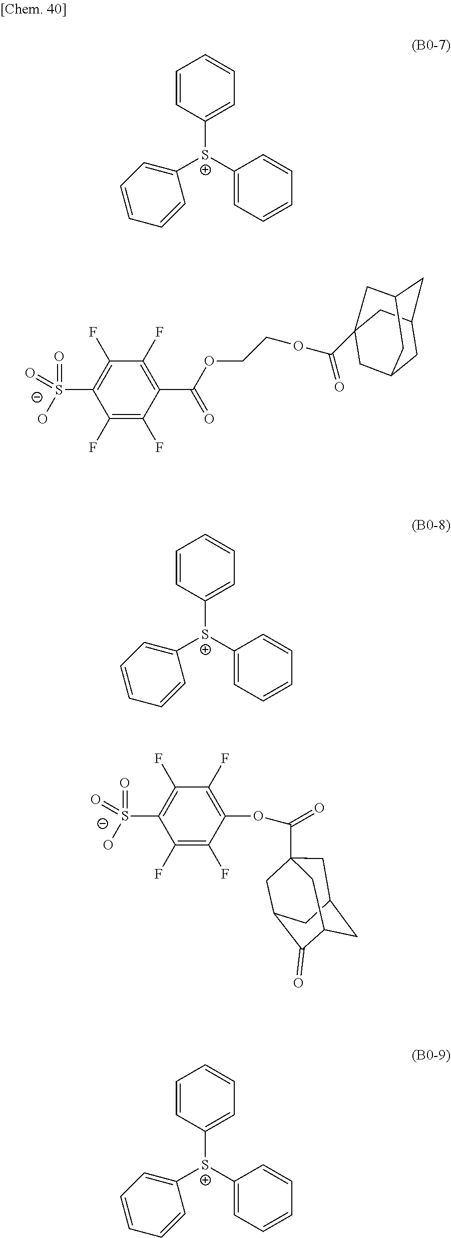 [SMILES: c1ccc([S+](c2ccccc2)c2ccccc2)cc1 ; O=C(OCCOC(=O)C12CC3CC(CC(C3)C1)C2)c1c(F)c(F)c(S(=O)(=O)[O-])c(F)c1F ; c1ccc([S+](c2ccccc2)c2ccccc2)cc1 ; O=C1C2CC3CC1CC(C(=O)Oc1c(F)c(F)c(S(=O)(=O)[O-])c(F)c1F)(C3)C2 ; c1ccc([S+](c2ccccc2)c2ccccc2)cc1]

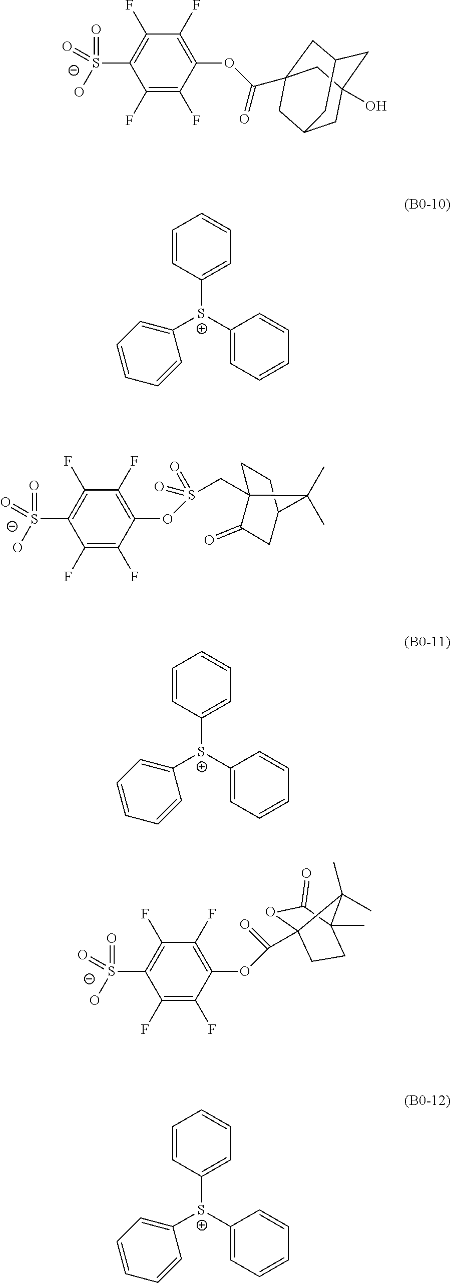 [SMILES: O=C(Oc1c(F)c(F)c(S(=O)(=O)[O-])c(F)c1F)C12CC3CC(CC(O)(C3)C1)C2 ; c1ccc([S+](c2ccccc2)c2ccccc2)cc1 ; CC1(C)C2CCC1(CS(=O)(=O)Oc1c(F)c(F)c(S(=O)(=O)[O-])c(F)c1F)C(=O)C2 ; c1ccc([S+](c2ccccc2)c2ccccc2)cc1 ; CC12CCC(C(=O)Oc3c(F)c(F)c(S(=O)(=O)[O-])c(F)c3F)(OC1=O)C2(C)C ; c1ccc([S+](c2ccccc2)c2ccccc2)cc1]

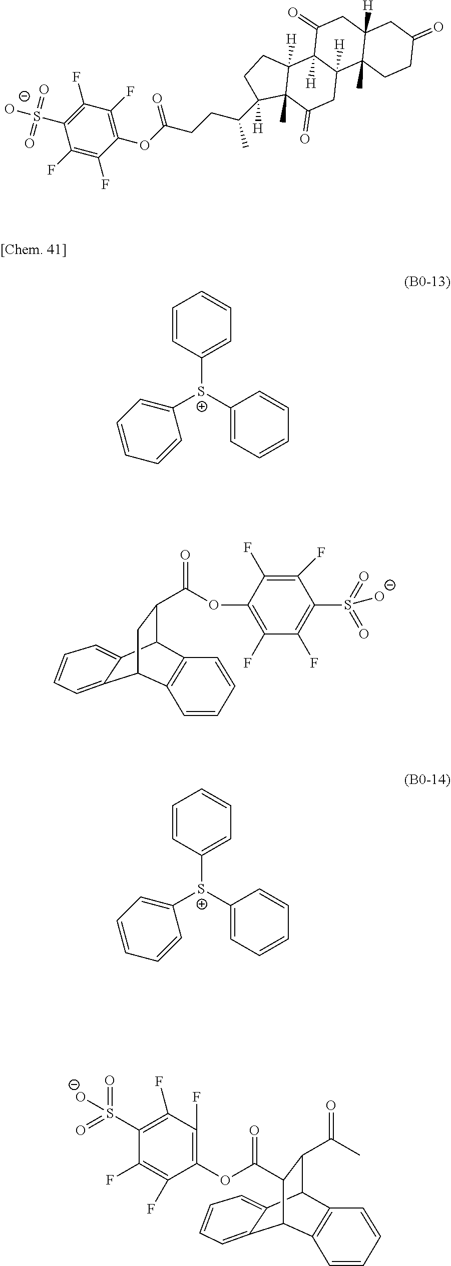

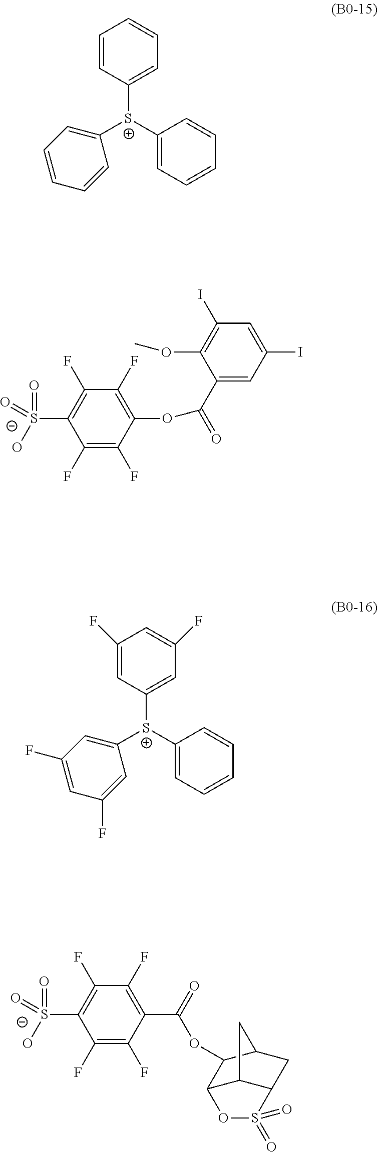 [SMILES: c1ccc([S+](c2ccccc2)c2ccccc2)cc1 ; COc1c(I)cc(I)cc1C(=O)Oc1c(F)c(F)c(S(=O)(=O)[O-])c(F)c1F ; Fc1cc(F)cc([S+](c2ccccc2)c2cc(F)cc(F)c2)c1 ; O=C(OC1C2CC3C1OS(=O)(=O)C3C2)c1c(F)c(F)c(S(=O)(=O)[O-])c(F)c1F]

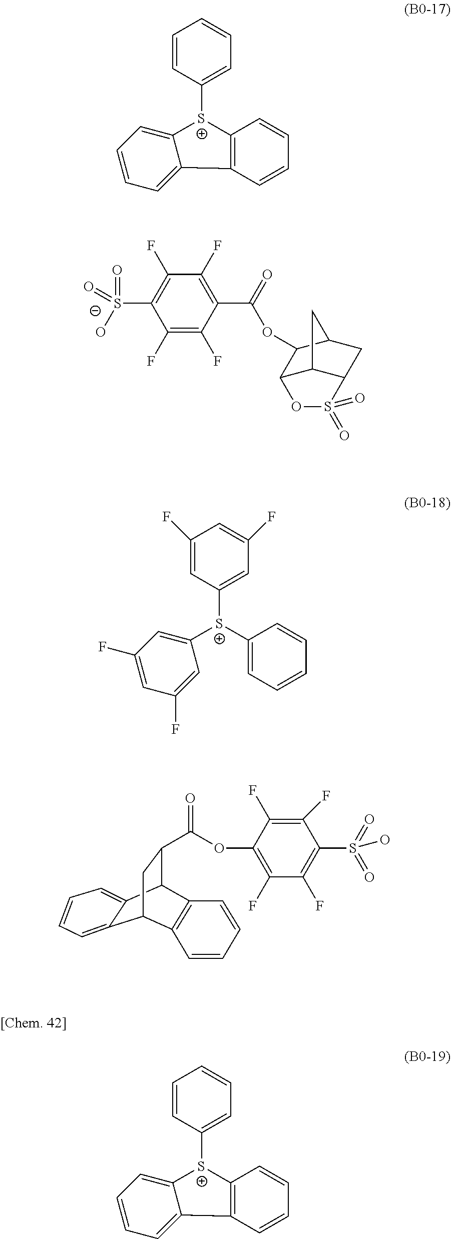 [SMILES: c1ccc(-[s+]2c3ccccc3c3ccccc32)cc1 ; O=C(OC1C2CC3C1OS(=O)(=O)C3C2)c1c(F)c(F)c(S(=O)(=O)[O-])c(F)c1F ; Fc1cc(F)cc([S+](c2ccccc2)c2cc(F)cc(F)c2)c1 ; O=C(Oc1c(F)c(F)c(S(=O)(=O)O)c(F)c1F)C1CC2c3ccccc3C1c1ccccc12 ; c1ccc(-[s+]2c3ccccc3c3ccccc32)cc1]

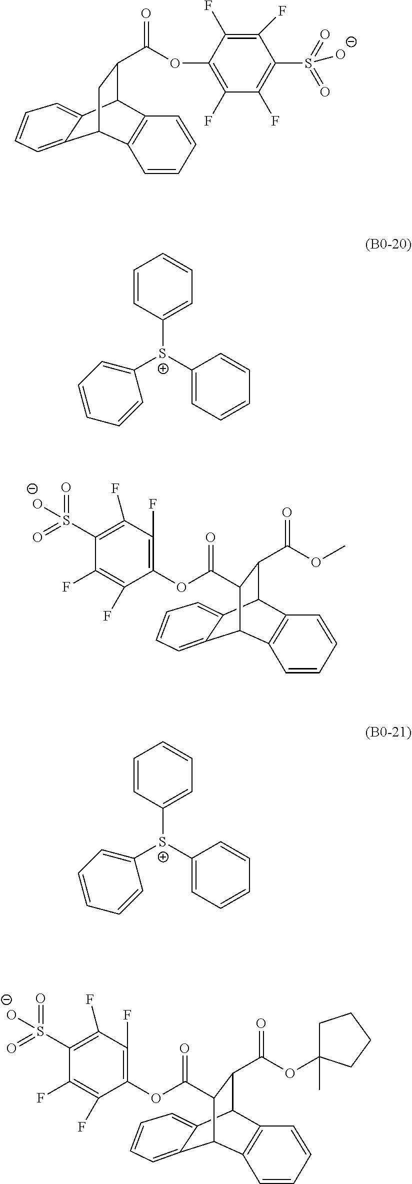 [SMILES: O=C(Oc1c(F)c(F)c(S(=O)(=O)[O-])c(F)c1F)C1CC2c3ccccc3C1c1ccccc12 ; c1ccc([S+](c2ccccc2)c2ccccc2)cc1 ; COC(=O)C1C2c3ccccc3C(c3ccccc32)C1C(=O)Oc1c(F)c(F)c(S(=O)(=O)[O-])c(F)c1F ; c1ccc([S+](c2ccccc2)c2ccccc2)cc1 ; CC1(OC(=O)C2C3c4ccccc4C(c4ccccc43)C2C(=O)Oc2c(F)c(F)c(S(=O)(=O)[O-])c(F)c2F)CCCC1]

A photoacid generating agent (B) may be used alone or two or more thereof may be used in combination. A content of the photoacid generating agent (B) is preferably 0.1 parts by mass or more and 30 parts by mass or less and more preferably 0.5 parts by mass or more and 20 parts by mass or less relative to 100 parts by mass of an acid-degradable compound (A). When the photoacid generating agent (B) is used in an amount falling within the above range, the desired effect is easily achieved.

### <Organic Solvent (S)>

A photosensitive composition preferably includes an organic solvent. Any organic solvent may be used as long as it can dissolve components to be used and form a homogeneous solution. Any organic solvent selected from conventionally known solvents as a solvent for a composition including a resin as a main component may be used.

Examples of the organic solvent include a lactone such as γ-butyrolactone; a ketone such as acetone, methyl ethyl ketone, cyclohexanone, methyl-n-pentyl ketone, methyl isopentyl ketone, or 2-heptanone; a polyhydric alcohol such as ethylene glycol, diethylene glycol, propylene glycol, or dipropylene glycol; a polyhydric alcohol monoacetate such as ethylene glycol monoacetate, diethylene glycol monoacetate, propylene glycol monoacetate, or dipropylene glycol monoacetate; a derivative of a polyhydric alcohol such as a compound having an ether bond such as a monoalkyl ether such as monomethyl ether, monoethyl ether, monopropyl ether, or monobutyl ether, or a monophenyl ether of the polyhydric alcohol or the polyhydric alcohol monoacetate [among these, propylene glycol monomethyl ether acetate (PGMEA) or propylene glycol monomethyl ether (PGME) is preferred]; a cyclic ether such as dioxane, or a polyhydric alcohol monoacetate and an ester other than the above-mentioned derivative of a polyhydric alcohol such as methyl lactate, ethyl lactate (EL), methyl acetate, ethyl acetate, butyl acetate, methyl pyruvate, ethyl pyruvate, methyl methoxy propionate, or ethyl ethoxy propionate; an aromatic organic solvent such as anisole, ethyl benzyl ether, cresyl methyl ether, diphenyl ether, dibenzyl ether, phenetole, butyl phenyl ether, ethyl benzene, diethyl benzene, pentyl benzene, isopropyl benzene, toluene, xylene, cymene, or mesitylene, etc. The organic solvent may be used alone, or two or more thereof may be used as a mixed solvent. Among these, propylene glycol monomethyl ether acetate (PGMEA), propylene glycol monomethyl ether (PGME), cyclohexanone, or ethyl lactate (EL) is preferred.

A content of an organic solvent in a photosensitive composition is not particularly limited. The organic solvent is appropriately set according to a coating thickness so that the photosensitive composition has a coatable concentration. The organic solvent is used so as to give a solid content concentration of the photosensitive composition of 0.2% by mass or more and 70% by mass or less and preferably 0.2% by mass or more and 50% by mass or less.

### <Other Components>

If desired, miscible additives such as an additional resin to improve performance of a lower layer film, a surfactant to improve coatability, a dissolution inhibiting agent, a plasticizing agent, a stabilizing agent, a coloring agent, an anti-halation agent, a dye, a sensitizing agent, a base multiplying agent, a basic compound, etc., can be added to the photosensitive composition, as appropriate.

### <<Compound>>

A compound is represented by any of Formulae (A1) to (A4). Detail and a preferred aspect of Formulae (A1) to (A4) are the same as those for Formulae (A1) to (A4) in the above-mentioned “photosensitive composition”.

### <<Method for Producing Structure Having Phase-Separated Structure>>

A method for producing a structure having a phase-separated structure includes forming a lower layer film on a substrate (hereinafter also referred to as “Step (i)”); forming an upper layer film including a block copolymer on the lower layer film (hereinafter also referred to as “Step (ii)”); and phase-separating the block copolymer in the upper layer film (hereinafter also referred to as “Step (iii)”).

<Step (i)>

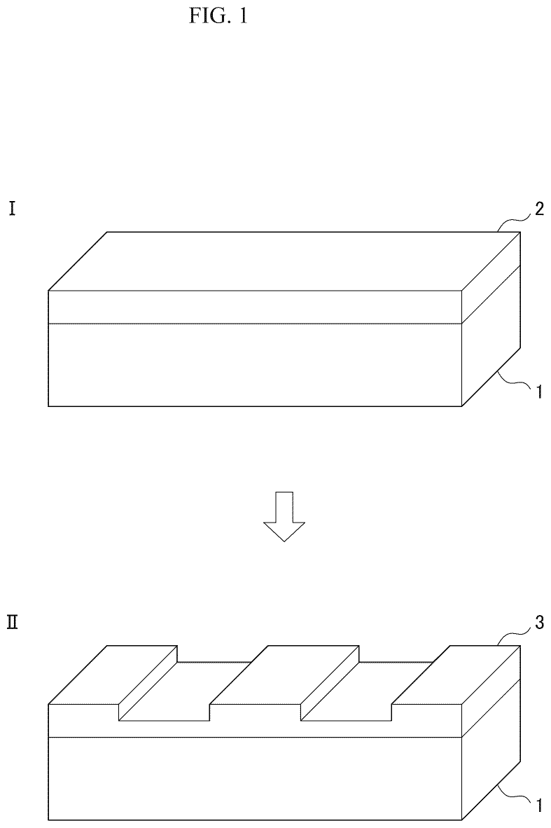

In Step (i), a lower layer film 3 is formed on a substrate 1. Step (i) will be specifically described with reference to FIG. 1.

In an embodiment shown in FIG. 1, a substrate 1 is first coated with a photosensitive composition to form a photosensitive film 2 (FIG. 1 (I)). Next, the photosensitive film 2 is exposed in a position-selective manner to form a lower layer film 3 (FIG. 1 (II)).

A kind of the substrate 1 is not particularly limited as long as its surface can be coated with the photosensitive composition. Examples thereof include a substrate made of an inorganic material such as silicon, a metal (e.g., copper, chromium, iron, aluminum, etc.), glass, titanium oxide, silica, or mica; a substrate made of an oxide such as SiO₂; a substrate made of a nitride such as SiN; a substrate made of an oxynitride such as SiON; or a substrate made of an organic material such as an acrylic resin, polystyrene, cellulose, cellulose acetate, or a phenolic resin. Among these, a silicon substrate (Si substrate) or a metal substrate is suitable, a Si substrate or a copper substrate (Cu substrate) is more suitable, and a Si substrate is particularly suitable. A size or shape of the substrate 1 is not particularly limited. The substrate 1 does not necessarily have a smooth surface, and substrates having various shapes can be appropriately selected therefor. For example, a substrate having a curved surface, a flat plate having an uneven surface, or a flaky substrate may be used.

An inorganic and/or organic film may be provided on a surface of the substrate 1. Examples of the inorganic film include an inorganic antireflection film (inorganic BARC), etc. Examples of the organic film include an organic antireflection film (organic BARC), etc. The inorganic film can be formed, for example, by coating a substrate with an inorganic antireflection film composition such as a silicon material and baking the resultant. The organic film can be formed, for example, by coating a substrate with a material for forming an organic film in which a resin component constituting the organic film, etc. is dissolved in an organic solvent using a spinner, etc., and baking the resultant under heating conditions at preferably 200° C. or more and 300° C. or less for preferably 30 seconds or more and 300 seconds or less and more preferably for 60 seconds or more and 180 seconds or less. This material for forming an organic film does not necessarily have sensitivity to light or electron beams like a resist film, and may or may not have the sensitivity. Specifically, a resist or a resin that has generally been used for producing a semiconductor element or a liquid crystal display element may be used. Furthermore, the material for forming an organic film is preferably a material capable of forming an organic film that can be subjected to etching, particularly dry-etching so that an organic film pattern may be formed on the organic film by etching the organic film using a pattern made of a block copolymer formed by processing the upper layer film to transfer the pattern onto the organic film. Among these, a material capable of forming an organic film that can be subjected to etching such as oxygen plasma etching is preferably used. Such a material for forming an organic film may be a material that has conventionally been used for forming an organic film such as organic BARC. Examples thereof include ARC series manufactured by Nissan Chemical Corporation, AR series manufactured by Rohm and Haas Japan Ltd., or SWK series manufactured by TOKYO OHKA KOGYO CO., LTD.

A method for forming the photosensitive film 2 by coating the substrate 1 with the photosensitive composition is not particularly limited and may be any conventionally known method. For example, the photosensitive film 2 can be formed by coating the substrate 1 with the photosensitive composition using a conventionally known method such as a spin coating or use of a spinner to form a coated film, and drying the coated film. Any method for drying the coated film may be used as long as a solvent included in the photosensitive composition can be volatilized to fix an acid-degradable compound (A) on the substrate 1, and, for example, baking may be used. In this case, a baking temperature is preferably 80° C. or more and 300° C. or less and more preferably 180° C. or more and 270° C. or less. A baking time is preferably 30 seconds or more and 600 seconds or less and more preferably 60 seconds or more and 600 seconds or less. A thickness of the photosensitive film 2 after drying the coated film is preferably about 1 nm or more and 150 nm or less and more preferably about 1 nm or more and 100 nm or less.

A surface of the substrate 1 may be pretreated. The surface of the substrate 1 can be treated to improve coatability of the photosensitive composition or easily fix an acid-degradable compound (A) on the substrate 1. A conventionally known surface treatment method such as an oxygen plasma treatment, an ozone oxidation treatment, an acid-alkali treatment, a chemical modification treatment, etc. can be used.

A method for exposing the photosensitive film 2 in a position-selective manner may be, for example, exposure through a mask. The exposure can be performed by irradiation with radiation such as UV, an ArF excimer laser, a KrF excimer laser, an F₂ excimer laser, extreme ultraviolet (EUV), vacuum ultraviolet (VUV), an electron beam, X-ray, soft X-ray, etc. An exposure dose is 10 mJ/cm² or more and 300 mJ/cm² or less, more preferably 20 mJ/cm² or more and 200 mJ/cm² or less, and further preferably 30 mJ/cm² or more and 150 mJ/cm² or less since polarity on a surface of the film can be changed by the exposure even under a low exposure dose condition.

The photosensitive film 2 after exposure is rinsed with a rinse liquid such as solvent. An acid-degradable portion in an acid-degradable compound (A) is removed by rinsing. Note that, the rinse liquid may be any liquid as long as it can dissolve the acid-degradable portion and a solvent such as propylene glycol monomethyl ether acetate (PGMEA), propylene glycol monomethyl ether (PGME), ethyl lactate (EL), or a commercially available thinner liquid may be used. After rinsing, post-baking is performed. A post-baking temperature is preferably 40° C. or more and 200° C. or less and more preferably 50° C. or more and 150° C. or less. A baking time is preferably 30 seconds or more and 300 seconds or less, more preferably 40 seconds or more and 200 seconds or less, and further preferably 50 seconds or more and 100 seconds or less.

These procedures result in a lower layer film including an exposed region and an unexposed region, the exposed region and the unexposed region differing in polarity (hydrophilicity) from each other. The lower layer film is used as a template for phase-separating a block copolymer in the below-mentioned step.

<Step (ii)>

In Step (ii), an upper layer film including a block copolymer is formed on a lower layer film 3. The block copolymer is not particularly limited, and a conventionally known block copolymer such as a block copolymer in which a block having a building block including an aromatic group and a block having a building block derived from an (α-substituted) acrylic acid ester are attached to each other (polystyrene-polymethyl methacrylate (PS-PMMA) block copolymer) can be used. A method of forming an upper layer film on the lower layer film 3 is not particularly limited, and, for example, may be a method including coating the lower layer film 3 with a resin composition for forming a phase-separated structure containing a block copolymer and an organic solvent by a conventionally known method such as spin coating or use of a spinner to form a coated film and then drying the coated film.

<Step (iii)>

In Step (iii), a block copolymer is phase-separated in an upper layer film. The substrate 1 after Step (ii) is heated for annealing to selectively remove a block copolymer. Thus, a phase-separated structure in which at least a portion of a surface of the substrate 1 is exposed is formed. In other words, a structure including a phase-separated structure is produced on the substrate 1.

### <Optional Step>

A method of producing a structure having a phase-separated structure may include a step other than Step (i) to Step (iii) (optional step). Such an optional step includes a step of selectively removing a phase made of at least one of blocks constituting a block copolymer from an upper layer film 3 (hereinafter referred to as “Step (iv)”).

### Step (iv)

In Step (iv), a phase made of at least one of blocks constituting a block copolymer is selectively removed from an upper layer film 2 formed on the lower layer film 3. This results in formation of a fine pattern (polymer nanostructure).

A method for selectively removing the phase made of the block may be a method for subjecting an upper layer film to an oxygen plasma treatment, a method for subjecting an upper layer film to a hydrogen plasma treatment, etc.

### Examples

Although the present invention will be described in more detail with reference to Examples, the present invention is not limited to Examples.

Materials used in Examples and Comparative Examples will be described below.

### <Acid Degradable Compound>

UL-1: Random copolymer having building blocks represented by formulae below (number average molecular weight: 15,200, dispersity: 1.29). A number at a lower right of a parenthesis in each of building blocks in the formulae represents a content (% by mole) of the building block in the copolymer.

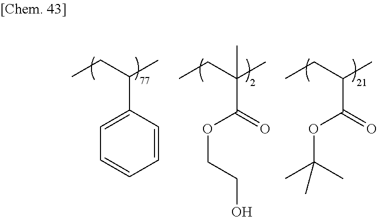

### [Synthesis of UL-2 Precursor and UL-2]

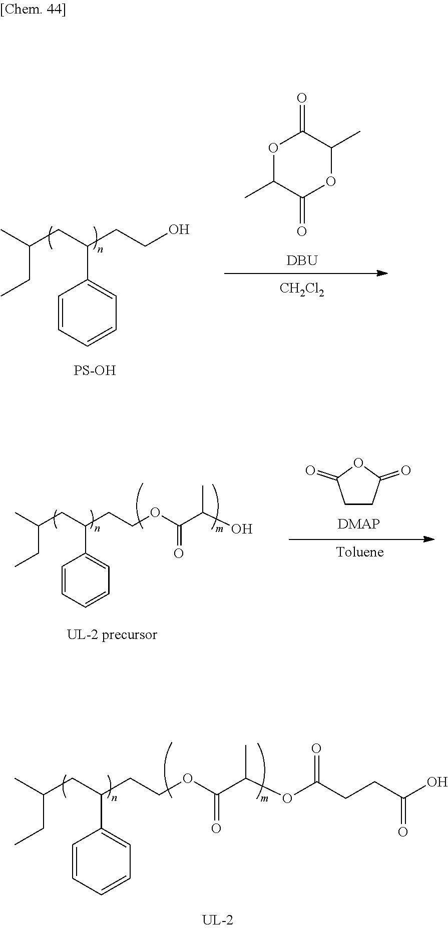

in which n is a number of repetitions of styrene units and m is a number of repetitions of lactic acid units.

All reactions were performed under an argon atmosphere. First, 5.0 g of polystyrene (PS—OH) (weight average molecular weight: 4,700) with a terminal hydroxy group and 2.1 g of DL-lactide were added to a 300 mL Schlenk tube, and then 5 mL of toluene was added thereto for azeotropic dehydration. After 20 g of dichloromethane was added to the Schlenk tube to dissolve a solid, 20 mg of diazabicycloundecene (DBU (registered trademark)) was added thereto and allowed to react at 25° C. A polymerization reaction was terminated by adding 20 mg of benzoic acid as a quenching agent. The resulting reaction solution was added to and re-precipitated into methanol. The resultant was dried under a reduced pressure at 40° C. to obtain a UL-2 precursor (5.80 g, yield: 82%) as a white powder. Then, 5.50 g of the UL-2 precursor (weight average molecular weight: 7,000), 367 mg succinic anhydride, and 150 mg 4-dimethylaminopyridine (DMAP) were added to a 300 mL Schlenk tube, and 55 g toluene was added thereto to dissolve a solid. The resulting solution in the Schlenk tube was heated and stirred in an oil bath at 120° C. for 13 hours. The resulting reaction solution was added to and reprecipitated into a mixed solution of isopropanol and heptane (8:2 (mass ratio)). The resultant was dried under a reduced pressure at 40° C. to obtain UL-2 (5.31 g, yield: 97%) as a white powder. A number average molecular weight (Mn) and dispersity (PDI=Mw/Mn) of the UL-2 as measured by size exclusion chromatography (SEC) were 8,000 and 1.06, respectively.

### [Synthesis of UL-3 Precursor and UL-3]

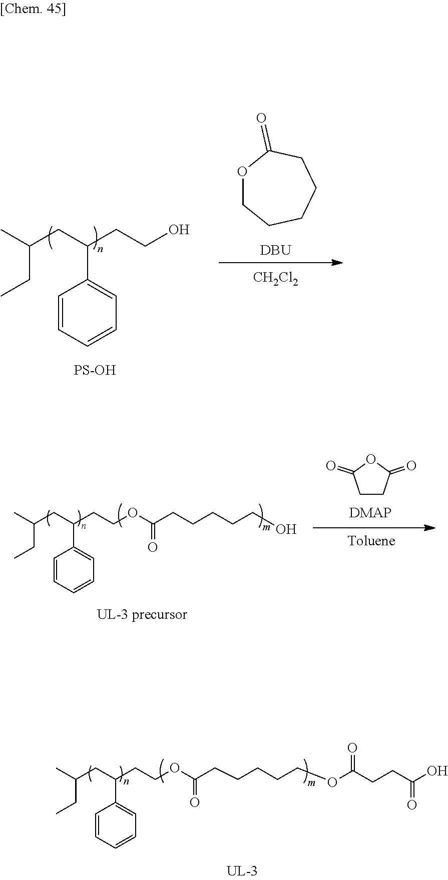

in which n is a number of repetitions of styrene units and m is a number of repetitions of ε-caprolactone units.

A UL-3 precursor (weight average molecular weight: 9,000) was obtained in the same manner as the synthesis of UL-2 precursor, except that ε-caprolactone was used instead of DL-lactide and a reaction temperature was changed from 25° C. to 40° C. UL-3 was obtained in the same manner as the synthesis of UL-2, except that the UL-3 precursor was used instead of the UL-2 precursor. A number average molecular weight (Mn) and dispersity (PDI=Mw/Mn) of the UL-3 as measured by size exclusion chromatography (SEC) were 10,000 and 1.06, respectively.

### <Photoacid Generating Agent>

PAG-1: Compound represented by the formula below.

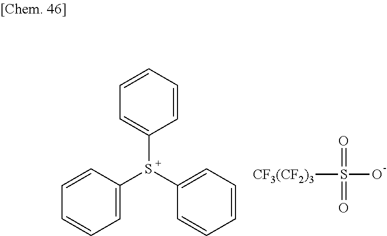

### <Preparation of Photosensitive Composition and Formation of Lower Layer Film>

Acid-degradable compounds in types shown in Table 1, a photoacid generating agent (PAG-1) in amounts shown in Table 1, propylene glycol monomethyl ether acetate, and propylene glycol monomethyl ether were mixed to prepare photosensitive compositions (solid concentration: 1.4% by mass) of Examples. An amount of the photoacid generating agent indicates part(s) by mass relative to 100 parts by mass of the acid-degradable compound.

A silicon wafer was coated with each of the photosensitive compositions of Examples using a spinner, and the resulting coated film was baked at 200° C. for 300 seconds under an atmospheric condition and rinsed with a mixed solvent of propylene glycol monomethyl ether and propylene glycol monomethyl ether acetate (8:2 (mass ratio)) to form a photosensitive film with a coating thickness of 2 nm. A KrF exposure device was used to irradiate the photosensitive film with a KrF excimer laser (wavelength: 248 nm) at each of exposure doses shown in Table 1. A surface of the photosensitive film was rinsed with a mixed solvent of propylene glycol monomethyl ether and propylene glycol monomethyl ether acetate (8:2 (mass ratio)) and then post-baked for 60 seconds at each of temperatures shown in Table 1 to form a lower layer film.

### <Water Contact Angle>

For each of the photosensitive films and the lower layer films formed using the photosensitive compositions of Examples, 2 μL of water was dropped onto its surface and a contact angle (static contact angle) was measured using DROP MASTER-700 (product name, manufactured by Kyowa Interface Science Co., Ltd) (elliptical fitting method). The thus-measured values are shown in Table 1 as “Water contact angle (photosensitive film) (°)” and “Water contact angle (lower layer film) (°)”.

TABLE 1

| | Acid | Amount of photoacid | | Exposure | Water contact angle | Water contact angle |
|---|---|---|---|---|---|---|
| | Degradable | generating agent | Temperature | dose | (Photosensitive film) | (Lower layer film) |
| | compound | (part(s) by mass) | (° C.) | (mJ/cm²) | (°) | (°) |
| Comparative | UL-1 | 1 | 60 | 40 | 82 | 82 |
| Example 1 | | | | | | |
| Comparative | UL-1 | 1 | 60 | 100 | 82 | 82 |
| Example 2 | | | | | | |
| Comparative | UL-1 | 3 | 60 | 40 | 82 | 82 |
| Example 3 | | | | | | |
| Comparative | UL-1 | 3 | 60 | 100 | 82 | 82 |
| Example 4 | | | | | | |
| Example 1 | UL-2 | 1 | 60 | 40 | 86 | 80 |
| Example 2 | UL-2 | 1 | 60 | 100 | 86 | 78 |
| Example 3 | UL-2 | 3 | 60 | 40 | 86 | 77 |
| Example 4 | UL-2 | 3 | 60 | 100 | 86 | 76 |
| Example 5 | UL-2 | 3 | 100 | 100 | 86 | 75 |
| Example 6 | UL-3 | 1 | 60 | 40 | 86 | 82 |
| Example 7 | UL-3 | 1 | 60 | 100 | 86 | 80 |
| Example 8 | UL-3 | 3 | 60 | 40 | 86 | 79 |
| Example 9 | UL-3 | 3 | 60 | 100 | 86 | 78 |
| Example 10 | UL-3 | 3 | 100 | 100 | 86 | 77 |

As shown in Table 1, for each of Examples 1 to 10 using a photosensitive composition including a predetermined acid-degradable compound (A) and a photoacid generating agent (B), a water contact angle of a lower layer film was smaller than that of a photosensitive film, in other words, polarity was changed even under low exposure dose and low post-baking temperature conditions. On the other hand, for each of Comparative Examples 1 to 4 using a photosensitive composition including a compound other than the predetermined acid-degradable compound (A), a water contact angle of a lower layer film was not different from that of a photosensitive film, in other words, polarity was not changed under low exposure dose and low post-baking temperature conditions. Therefore, it demonstrates that a guide pattern with different polarity can be formed even under low exposure dose and low post-baking temperature conditions by using the photosensitive composition including the predetermined acid-degradable compound (A) and performing exposure in a position-selective manner.

What is claimed is:

1. A photosensitive composition, comprising an acid-degradable compound (A) and a photoacid generating agent (B),
wherein the acid-degradable compound (A) is one or more compounds represented by any of Formulae (A1) to (A4) below:
R^{a1}—(—CH₂—CR^{a2}R^{a3}—)ₙ—R^{a4}—O—(—CO—R^{a5}—CO—)—O—R^{a6}—R^{a7} (A1)
R^{a1}—(—CH₂—CR^{a2}R^{a3}—)ₙ—R^{a4}—O—(—CO—R^{a5}—O—)—CO—R^{a6}—R^{a7} (A2)
R^{a1}—(—CH₂—CR^{a2}R^{a3}—)ₙ—R^{a4}—CO—(—O—R^{a5}—CO—)—O—R^{a6}—R^{a7} (A3)
R^{a1}—(—CH₂—CR^{a2}R^{a3}—)ₙ—R^{a4}—CO—(—O—R^{a5}—O—)—CO—R^{a6}—R^{a7} (A4)
wherein R^{a1} is an alkyl group, R^{a2} is a hydrogen atom or an alkyl group, R^{a3} is an aromatic group that may have a substituent, R^{a4} is an alkylene group, R^{a5} is a residue in which a carboxy group or a hydroxy group as a terminal group is removed from a linear aliphatic polyester, R^{a6} is an alkylene group, R^{a7} is a hydroxy group, a carboxy group, a phosphate group, a mercapto group, or an amino group, and n is a number of replications of a building block represented by —CH₂—CR^{a2}R^{a3}— and is an integer of 2 or more.

2. The photosensitive composition according to claim 1, wherein the aromatic group that may have a substituent for R^{a3} is an aromatic hydrocarbon group that may have a substituent.

3. The photosensitive composition according to claim 1, wherein the linear aliphatic polyester for R^{a5} is a polycondensate of an aliphatic hydroxycarboxylic acid or a ring-opened polymer of a lactone.

4. The photosensitive composition according to claim 3, wherein the polycondensate of an aliphatic hydroxycarboxylic acid or the ring-opened polymer of a lactone is one or more selected from the group consisting of polylactic acid, polyglycolic acid, polyhydroxybutyric acid, polycaprolactone, polybutyrolactone, and polyvalerolactone.

5. A photosensitive film comprising an acid-degradable compound (A) and a photoacid generating agent (B),
wherein the acid-degradable compound (A) is one or more compounds represented by any of Formulae (A1) to (A4) below:
R^{a1}—(—CH₂—CR^{a2}R^{a3}—)ₙ—R^{a4}—O—(—CO—R^{a5}—CO—)—O—R^{a6}—R^{a7} (A1)
R^{a1}—(—CH₂—CR^{a2}R^{a3}—)ₙ—R^{a4}—O—(—CO—R^{a5}—O—)—CO—R^{a6}—R^{a7} (A2)
R^{a1}—(—CH₂—CR^{a2}R^{a3}—)ₙ—R^{a4}—CO—(—O—R^{a5}—CO—)—O—R^{a6}—R^{a7} (A3)
R^{a1}—(—CH₂—CR^{a2}R^{a3}—)ₙ—R^{a4}—CO—(—O—R^{a5}—O—)—CO—R^{a6}—R^{a7} (A4)
wherein R^{a1} is an alkyl group, R^{a2} is a hydrogen atom or an alkyl group, R^{a3} is an aromatic group that may have a substituent, R^{a4} is an alkylene group, R^{a5} is a residue in which a carboxy group or a hydroxy group as a terminal group is removed from a linear aliphatic polyester, R^{a6} is an alkylene group, R^{a7} is a hydroxy group, a carboxy group, a phosphate group, a mercapto group, or an amino group, and n is a number of replications of a building block represented by —CH₂—CR^{a2}R^{a3}— and is an integer of 2 or more.

6. A lower layer film for use as a template for phase-separating a block copolymer,
wherein the lower layer film is formed by exposing the photosensitive film according to claim 5 in a position-selective manner, and
the lower layer film comprises an exposed region and an unexposed region, wherein the exposed region and the unexposed region differ in hydrophilicity from each other.

7. A method for producing a structure having a phase-separated structure, the method comprising:
forming the lower layer film according to claim 6 on a substrate;
forming an upper layer film on the lower layer film, the upper layer film comprising a block copolymer; and
phase-separating the block copolymer in the upper layer film.

8. A compound represented by any of Formulae (A1) to (A4) below:
R^{a1}—(—CH₂—CR^{a2}R^{a3}—)ₙ—R^{a4}—O—(—CO—R^{a5}—CO—)—O—R^{a6}—R^{a7} (A1)
R^{a1}—(—CH₂—CR^{a2}R^{a3}—)ₙ—R^{a4}—O—(—CO—R^{a5}—O—)—CO—R^{a6}—R^{a7} (A2)
R^{a1}—(—CH₂—CR^{a2}R^{a3}—)ₙ—R^{a4}—CO—(—O—R^{a5}—CO—)—O—R^{a6}—R^{a7} (A3)
R^{a1}—(—CH₂—CR^{a2}R^{a3}—)ₙ—R^{a4}—CO—(—O—R^{a5}—O—)—CO—R^{a6}—R^{a7} (A4)
wherein R^{a1} is an alkyl group, R^{a2} is a hydrogen atom or an alkyl group, R^{a3} is an aromatic group that may have a substituent, R^{a4} is an alkylene group, R^{a5} is a residue in which a carboxy group or a hydroxy group as a terminal group is removed from a linear aliphatic polyester, R^{a6} is an alkylene group, R^{a7} is a hydroxy group, a carboxy group, a phosphate group, a mercapto group, or an amino group, and n is a number of replications of a building block represented by —CH₂—CR^{a2}R^{a3}— and is an integer of 2 or more.
